(19) United States
(12) Patent Application Publication
(10) Pub. No.: US 2023/0088847 A1
(43) Pub. Date: Mar. 23, 2023

(54) OPTICAL LAMINATE, POLARIZING PLATE, AND IMAGE DISPLAY DEVICE

(71) Applicant: FUJIFILM Corporation, Tokyo (JP)

(72) Inventors: Kunihiro ATSUMI, Kanagawa (JP); Kazushige NAKAGAWA, Kanagawa (JP); Yutaka NOZOE, Kanagawa (JP); Takashi IIZUMI, Kanagawa (JP); Soichiro WATANABE, Kanagawa (JP)

(73) Assignee: FUJIFILM Corporation, Tokyo (JP)

(21) Appl. No.: 17/889,380

(22) Filed: Aug. 16, 2022

Related U.S. Application Data
(63) Continuation of application No. PCT/JP2021/003541, filed on Feb. 1, 2021.

(30) Foreign Application Priority Data
Feb. 20, 2020 (JP) 2020-027051
Jan. 21, 2021 (JP) 2021-007888

(51) Int. Cl. G02F 1/13363; G02F 1/1335; G02F 1/1337; C09K 19/56; B32B 27/08

(52) U.S. Cl. CPC G02F 1/133632; G02F 1/133528; G02F 1/133711; G02F 1/133788; C09K 19/56; B32B 27/08; C09K 2323/03; B32B 2305/55; B32B 2307/40

(57) ABSTRACT

An object of the present invention is to provide an optical laminate in which an optically anisotropic layer provided as an upper layer has good liquid crystal alignment properties, and a polarizing plate and an image display device using the optical laminate. An optical laminate of the present invention is an optical laminate including: a first optically anisotropic layer; and a second optically anisotropic layer, in which the first and second optically anisotropic layers are directly laminated, each of the first and second optically anisotropic layers consists of a liquid crystal layer, and a photo-alignment polymer having a photo-alignment group and at least one type of polar group selected from the group consisting of a hydroxyl group and a ketone group is present in a surface of the second optically anisotropic layer on a side in contact with the first optically anisotropic layer.

### CROSS-REFERENCE TO RELATED APPLICATIONS

This application is a Continuation of PCT International Application No. PCT/JP2021/003541 filed on Feb. 1, 2021, which claims priority under 35 U.S.C. § 119(a) to Japanese Patent Application No. 2020-027051 filed on Feb. 20, 2020 and Japanese Patent Application No. 2021-007888 filed on Jan. 21, 2021. Each of the above applications is hereby expressly incorporated by reference, in its entirety, into the present application.

### BACKGROUND OF THE INVENTION

### 1. Field of the Invention

The present invention relates to an optical laminate, a polarizing plate, and an image display device.

### 2. Description of the Related Art

Optical films such as optical compensation sheets or retardation films are used in various image display devices from the viewpoint of solving image staining or enlarging a view angle.

A stretched birefringence film has been used as an optical film, but in recent years, it has been proposed to use an optically anisotropic layer formed of a liquid crystal compound in place of the stretched birefringence film.

In the formation of such an optically anisotropic layer, a photo-alignment film obtained by performing a photo-alignment treatment may be used in order to align the liquid crystal compound.

For example, examples of WO2018/216812A disclose a method of forming an optically anisotropic layer using a photo-alignment polymer represented by the following formula. The photo-alignment polymer contains a cleavage group which is decomposed by the action of an acid to produce a polar group.

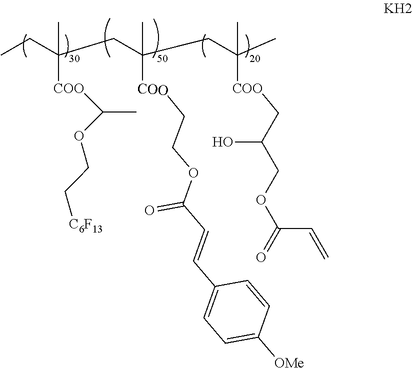

### SUMMARY OF THE INVENTION

Recently, in an optically anisotropic layer formed of a liquid crystal compound, it has been required to further improve aligning properties of the liquid crystal compound.

The inventors have conducted studies on the photo-alignment polymer described in detail in WO2018/216812A, and found that the aligning properties (hereinafter, also abbreviated as “liquid crystal alignment properties”) of the liquid crystal compound in an optically anisotropic layer formed on a layer formed of the photo-alignment polymer meet a level required in the past, but do not meet a higher level required these days, and a further improvement is required.

Therefore, an object of the present invention is to provide an optical laminate in which an optically anisotropic layer provided as an upper layer has good liquid crystal alignment properties, and a polarizing plate and an image display device using the optical laminate.

The inventors have conducted intensive studies to achieve the object, and as a result, found that in a case where in an optical laminate obtained by directly laminating first and second optically anisotropic layers, each of which consists of a liquid crystal layer, a photo-alignment polymer having a photo-alignment group and at least one type of polar group selected from the group consisting of a hydroxyl group and a ketone group is present in a surface of the second optically anisotropic layer on the side in contact with the first optically anisotropic layer, the liquid crystal alignment properties of the first optically anisotropic layer as an upper layer are improved, and completed the present invention.

That is, the inventors have found that the object can be achieved with the following configuration.

[1] An optical laminate having: a first optically anisotropic layer; and a second optically anisotropic layer, in which the first and second optically anisotropic layers are directly laminated,

each of the first and second optically anisotropic layers consists of a liquid crystal layer, and

a photo-alignment polymer having a photo-alignment group and at least one type of polar group selected from the group consisting of a hydroxyl group and a ketone group is present in a surface of the second optically anisotropic layer on a side in contact with the first optically anisotropic layer.

[2] The optical laminate according to [1], in which a molar ratio of the polar group to the photo-alignment group is 0.8 to 4.0.

[3] The optical laminate according to [1] or [2], in which the photo-alignment group is a cinnamoyl group bonded to a main chain of the photo-alignment polymer via a linking group containing a cycloalkane ring.

[4] The optical laminate according to any one of [1] to [3], in which the polar group is bonded to a main chain of the photo-alignment polymer via a linking group containing an aliphatic hydrocarbon group having one or more carbon atoms.

[5] The optical laminate according to any one of [1] to [4], in which fluorine or silicon is substantially not present in the surface of the second optically anisotropic layer on the side in contact with the first optically anisotropic layer.

[6] The optical laminate according to any one of [1] to [5], in which the first optically anisotropic layer is a positive A plate.

[7] The optical laminate according to any one of [1] to [6], in which the second optically anisotropic layer is a positive C plate.

[8] The optical laminate according to any one of [1] to [5], in which the first optically anisotropic layer is a positive C plate.

[9] The optical laminate according to any one of [1] to [5] and [8], in which the second optically anisotropic layer is a positive A plate.

[10] A polarizing plate having: the optical laminate according to any one of [1] to [9]; and a polarizer.

[11] An image display device having: the optical laminate according to any one of [1] to [9]; or the polarizing plate according to [10].

According to the present invention, it is possible to provide an optical laminate in which an optically anisotropic layer provided as an upper layer has good liquid crystal alignment properties, and a polarizing plate and an image display device using the optical laminate.

### DESCRIPTION OF THE PREFERRED EMBODIMENTS

Hereinafter, the present invention will be described in detail.

The following description of constituent requirements is based on representative embodiments of the present invention, but the present invention is not limited to the embodiments.

In this specification, a numerical range expressed using “to” means a range including numerical values before and after “to” as a lower limit and an upper limit.

In addition, in this specification, as each component, a substance corresponding to each component may be used alone, or two or more types of substances may be used in combination. Here, in a case where two or more types of substances are used in combination for each component, the content of the component refers to a total content of the substances used in combination unless otherwise specified.

In addition, the bonding direction of a divalent group (for example, —O—CO—) described in this specification is not particularly limited, and for example, in a case where L² in a “L¹-L²-L³” bond is —O—CO—, and a bonding position on the L¹ side is represented by *1 and a bonding position on the L³ side is represented by *2, L² may be *1-O—CO—*2 or *1-CO—O—O—*2.

In the present invention, Re (λ) and Rth (λ) represent an in-plane retardation and a thickness-direction retardation at a wavelength λ, respectively. Unless otherwise specified, the wavelength λ is 550 nm.

In the present invention, Re (λ) and Rth (λ) are values measured at a wavelength λ by AxoScan, manufactured by Axometrics, Inc. By inputting an average refractive index ((nx+ny+nz)/3) and a film thickness (d(μm)) by AxoScan,
Slow Axis Direction (°)
Re (λ)=R0 (λ)
Rth (λ)=((nx+ny)/2−nz)×d
are calculated.

R0 (λ) is displayed as a numerical value calculated by AxoScan, and means Re (λ).

In this specification, refractive indices nx, ny, and nz are measured using an Abbe's refractometer (NAR-4T, manufactured by Atago Co., Ltd.) and a sodium lamp (λ=589 nm) as a light source. In addition, in the measurement of wavelength dependency, the wavelength dependency can be measured by a multi-wavelength Abbe refractometer DR-M2 (manufactured by ATAGO CO., LTD.) in combination with a dichroic filter.

In addition, values in Polymer Handbook (JOHN WILEY & SONS, INC) and catalogs of various optical films can be used. Examples of the average refractive indices of main optical films are as follows: cellulose acylate (1.48), cycloolefin polymer (1.52), polycarbonate (1.59), polymethylmethacrylate (1.49), and polystyrene (1.59).

[Optical Laminate]

An optical laminate according to an embodiment of the present invention is an optical laminate in which first and second optically anisotropic layers are directly laminated.

In addition, in the optical laminate according to the embodiment of the present invention, each of the first and second optically anisotropic layers consists of a liquid crystal layer.

In addition, in the optical laminate according to the embodiment of the present invention, a photo-alignment polymer having a photo-alignment group and at least one type of polar group selected from the group consisting of a hydroxyl group and a ketone group is present in a surface of the second optically anisotropic layer on the side in contact with the first optically anisotropic layer.

The thickness of the optical laminate is not particularly limited, and is preferably 0.2 to 10 μm, more preferably 0.5 to 5 μm, and even more preferably 1 to 4 μm.

In the optical laminate according to the embodiment of the present invention, since the adhesiveness between the first optically anisotropic layer and the second optically anisotropic layer is improved, and cissing is suppressed due to improved liquid crystal alignment properties of the optically anisotropic layer provided as an upper layer, it is preferable that fluorine and silicon are substantially not present in an interface between the second optically anisotropic layer and the first optically anisotropic layer.

Here, the expression “substantially not present” means that the content, measured by X-ray photoelectron spectroscopy (X-ray photoelectron spectroscopy or ESCA: electron spectroscopy for chemical analysis: XPS), is equal to or less than a detection value (0.1% or less).

In the following description, first, the second optically anisotropic layer having a photo-alignment polymer will be described in detail, and then the first optically anisotropic layer as an upper layer will be described in detail.

[Second Optically Anisotropic Layer]

In the optical laminate according to the embodiment of the present invention, a photo-alignment polymer (hereinafter, formally abbreviated as “photo-alignment polymer of the present invention”) having a photo-alignment group and at least one type of polar group selected from the group consisting of a hydroxyl group and a ketone group is present in a surface of the second optically anisotropic layer on the side in contact with the first optically anisotropic layer.

Here, the surface of the second optically anisotropic layer on the side in contact with the first optically anisotropic layer refers to a surface layer region from the interface between the second optically anisotropic layer and the first optically anisotropic layer to 20 nm deep in a thickness direction of the second optically anisotropic layer, and is also abbreviated as “surface layer A” below.

In addition, the presence of the photo-alignment polymer in the surface layer A of the second optically anisotropic layer can be confirmed by, for example, time-of-flight secondary ion mass spectrometry (TOF-SIMS). As the TOF-SIMS method, the method described in “Surface Analysis Technique Selection, Secondary Ion Mass Spectrometry” edited by Japanese Society of Surface Science, MARUZEN GROUP (published in 1999), can be adopted.

Specifically, in a case where a photo-alignment polymer having a photo-alignment group and a polar group is present in the surface of the second optically anisotropic layer on the side in contact with the first optically anisotropic layer, that is, the interface between the first optically anisotropic layer and the second optically anisotropic layer, fragments derived from the photo-alignment group and fragments derived from a unit having the polar group are both detected at the same position near the interface.

In addition, the composition distribution of the first and second optically anisotropic layers in the thickness direction is analyzed by repeating the ion beam irradiation and the measurement with TOF-SIMS from the air interface side of the first or second optically anisotropic layer. For the ion beam irradiation and the measurement with TOF-SIMS, a series of operations in which component analysis is performed on the region (hereinafter, “surface region”) from the surface to 1 to 2 nm deep in the thickness direction, and then performed on the next surface region 1 to several hundred nanometers deeper than the above region in the thickness direction is repeated.

The distribution of the photo-alignment polymer in the thickness direction of the first and second optically anisotropic layers is analyzed by measuring the secondary ion intensity derived from the unit having the photo-alignment group and the unit having the polar group.

Examples of the type of ion beams include ion beams generated by an argon gas cluster ion gun (Ar-GCIB gun).

<Photo-Alignment Polymer>

As described above, the photo-alignment polymer of the present invention is a photo-alignment polymer having a photo-alignment group and at least one type of polar group selected from the group consisting of a hydroxyl group and a ketone group.

In the present invention, since the liquid crystal alignment properties of the first optically anisotropic layer are improved, the molar ratio of the polar group to the photo-alignment group of the photo-alignment polymer is preferably 0.8 to 4.0, and more preferably 0.9 to 2.0.

Here, the molar ratio of the polar group to the photo-alignment group can be measured and calculated by solid-state nuclear magnetic resonance (NMR). Specifically, by analyzing cutting chips obtained by scraping a range of about 200 nm in film thickness, including the interface between the first optically anisotropic layer and the second optically anisotropic layer, using solid ¹H-NMR and solid ¹³C-NMR, the molar ratio of the polar group to the photo-alignment group can be calculated.

In addition, in the present invention, since the liquid crystal alignment properties of the first optically anisotropic layer are improved, the photo-alignment group of the photo-alignment polymer is preferably a cinnamoyl group bonded to a main chain of the photo-alignment polymer via a linking group containing a cycloalkane ring.

Furthermore, in the present invention, since the liquid crystal alignment properties of the first optically anisotropic layer are improved, the polar group of the photo-alignment polymer is preferably bonded to a main chain of the photo-alignment polymer via a linking group containing an aliphatic hydrocarbon group having one or more carbon atoms.

Since the adhesiveness between the first optically anisotropic layer and the second optically anisotropic layer is improved, the photo-alignment polymer of the present invention is preferably a copolymer having a repeating unit containing a photo-alignment group and a repeating unit containing a polar group.

(Repeating Unit Containing Photo-Alignment Group)

Examples of the repeating unit containing a photo-alignment group include a repeating unit represented by Formula (A) (hereinafter, also abbreviated as “repeating unit A”).

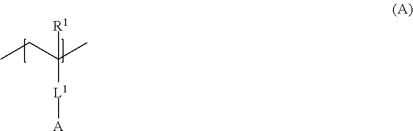

In Formula (A), R¹ represents a hydrogen atom or a substituent, L¹ represents a divalent linking group, and A represents a photo-alignment group.

Next, the hydrogen atom or substituent represented by R¹ in Formula (A) will be described.

In Formula (A), the substituent represented by one aspect of R¹ is preferably a halogen atom, a linear alkyl group having 1 to 20 carbon atoms, a branched or cyclic alkyl group having 3 to 20 carbon atoms, a linear halogenated alkyl group having 1 to 20 carbon atoms, an alkoxy group having 1 to 20 carbon atoms, an aryl group having 6 to 20 carbon atoms, an aryloxy group having 6 to 20 carbon atoms, a cyano group, or an amino group.

Examples of the halogen atom include a fluorine atom, a chlorine atom, a bromine atom, and an iodine atom. Among these, a fluorine atom and a chlorine atom are preferable.

The linear alkyl group having 1 to 20 carbon atoms is preferably an alkyl group having 1 to 6 carbon atoms, and specific examples thereof include a methyl group, an ethyl group, and an n-propyl group.

The branched alkyl group having 3 to 20 carbon atoms is preferably an alkyl group having 3 to 6 carbon atoms, and specific examples thereof include an isopropyl group and a tert-butyl group.

The cyclic alkyl group having 3 to 20 carbon atoms is preferably an alkyl group having 3 to 6 carbon atoms, and specific examples thereof include a cyclopropyl group, a cyclopentyl group, and a cyclohexyl group.

The linear halogenated alkyl group having 1 to 20 carbon atoms is preferably a fluoroalkyl group having 1 to 4 carbon atoms.

The alkoxy group having 1 to 20 carbon atoms is preferably an alkoxy group having 1 to 18 carbon atoms, more preferably an alkoxy group having 6 to 18 carbon atoms, and even more preferably an alkoxy group having 6 to 14 carbon atoms.

The aryl group having 6 to 20 carbon atoms is preferably an aryl group having 6 to 12 carbon atoms, and specific examples thereof include a phenyl group, an α-methylphenyl group, and a naphthyl group. Among these, a phenyl group is preferable.

The aryloxy group having 6 to 20 carbon atoms is preferably an aryloxy group having 6 to 12 carbon atoms, and specific examples thereof include a phenyloxy group and a 2-naphthyloxy group. Among these, a phenyloxy group is preferable.

Examples of the amino group include: primary amino groups (—NH₂); secondary amino groups such as a methylamino group; and tertiary amino groups such as a dimethylamino group, a diethylamino group, a dibenzylamino group, and a group having a nitrogen atom of a nitrogen-containing heterocyclic compound (for example, pyrrolidine, piperidine, and piperazine) as a bonding site.

Next, the divalent linking group represented by L¹ in Formula (A) will be described.

Since the liquid crystal alignment properties of the first optically anisotropic layer are improved, the divalent linking group is preferably a divalent linking group obtained by combining at least two selected from the group consisting of a linear alkylene group having 1 to 18 carbon atoms which may have a substituent, a branched alkylene group having 3 to 18 carbon atoms which may have a substituent, a cyclic alkylene group having 3 to 18 carbon atoms which may have a substituent, an arylene group having 6 to 12 carbon atoms which may have a substituent, an ether group (—O—), a carbonyl group (—C(═O)—), and an imino group (—NH—) which may have a substituent.

Here, examples of the substituent that the alkylene group, the arylene group, and the imino group may have include a halogen atom, an alkyl group, an alkoxy group, an aryl group, an aryloxy group, a cyano group, a carboxy group, an alkoxycarbonyl group, and a hydroxyl group.

Examples of the halogen atom include a fluorine atom, a chlorine atom, a bromine atom, and an iodine atom. Among these, a fluorine atom and a chlorine atom are preferable.

The alkyl group is, for example, preferably an alkyl group having 1 to 18 carbon atoms, more preferably an alkyl group having 1 to 8 carbon atoms (for example, a methyl group, an ethyl group, a propyl group, an isopropyl group, an n-butyl group, an isobutyl group, a sec-butyl group, a t-butyl group, a cyclohexyl group, and the like), even more preferably an alkyl group having 1 to 4 carbon atoms, and particularly preferably a methyl group or an ethyl group.

The alkoxy group is, for example, preferably an alkoxy group having 1 to 18 carbon atoms, more preferably an alkoxy group having 1 to 8 carbon atoms (for example, a methoxy group, an ethoxy group, an n-butoxy group, a methoxyethoxy group, and the like), even more preferably an alkoxy group having 1 to 4 carbon atoms, and particularly preferably a methoxy group or an ethoxy group.

Examples of the aryl group include an aryl group having 6 to 12 carbon atoms. Specific examples thereof include a phenyl group, an α-methylphenyl group, and a naphthyl group. Among these, a phenyl group is preferable.

Examples of the aryloxy group include phenoxy, naphthoxy, imidazoyloxy, benzimidazoyloxy, pyridine-4-yloxy, pyrimidinyloxy, quinazolinyloxy, purinyloxy, and thiophen-3-yloxy.

Examples of the alkoxycarbonyl group include methoxycarbonyl and ethoxycarbonyl.

Specific examples of the linear alkylene group having 1 to 18 carbon atoms include a methylene group, an ethylene group, a propylene group, a butylene group, a pentylene group, a hexylene group, a decylene group, an undecylene group, a dodecylene group, a tridecylene group, a tetradecylene group, a pentadecylene group, a hexadecylene group, a heptadecylene group, and an octadecylene group.

In addition, specific examples of the branched alkylene group having 3 to 18 carbon atoms include a dimethylmethylene group, a methylethylene group, a 2,2-dimethylpropylene group, and a 2-ethyl-2-methylpropylene group.

Specific examples of the cyclic alkylene group having 3 to 18 carbon atoms include a cyclopropylene group, a cyclobutylene group, a cyclopentylene group, a cyclohexylene group, a cyclooctylene group, a cyclodecylene group, an adamantane-diyl group, a norbornane-diyl group, and an exo-tetrahydrodicyclopentadiene-diyl group. Among these, a cyclohexylene group is preferable.

Specific examples of the arylene group having 6 to 12 carbon atoms include a phenylene group, a xylylene group, a biphenylene group, a naphthylene group, and a 2,2′-methylenebisphenyl group. Among these, a phenylene group is preferable.

In the present invention, since the liquid crystal alignment properties of the first optically anisotropic layer are improved, L¹ in Formula (A) preferably represents a divalent linking group containing a cycloalkane ring, and more preferably represents a divalent linking group containing a nitrogen atom and a cycloalkane ring.

In this preferable aspect, a part of carbon atoms constituting the cycloalkane ring may be substituted with a hetero atom selected from the group consisting of nitrogen, oxygen, and sulfur. In addition, in a case where a part of carbon atoms constituting the cycloalkane ring is substituted with a nitrogen atom, no nitrogen atom may be contained separately from the cycloalkane ring.

Here, the cycloalkane ring is preferably a cycloalkane ring having 6 or more carbon atoms, and specific examples thereof include a cyclohexane ring, a cycloheptane ring, a cyclooctane ring, a cyclododecane ring, and a cyclodocosane ring.

In addition, in the present invention, since the liquid crystal alignment properties of the first optically anisotropic layer are improved, L¹ in Formula (A) is preferably a divalent linking group represented by any one of Formula (3), . . . , or Formula (12).

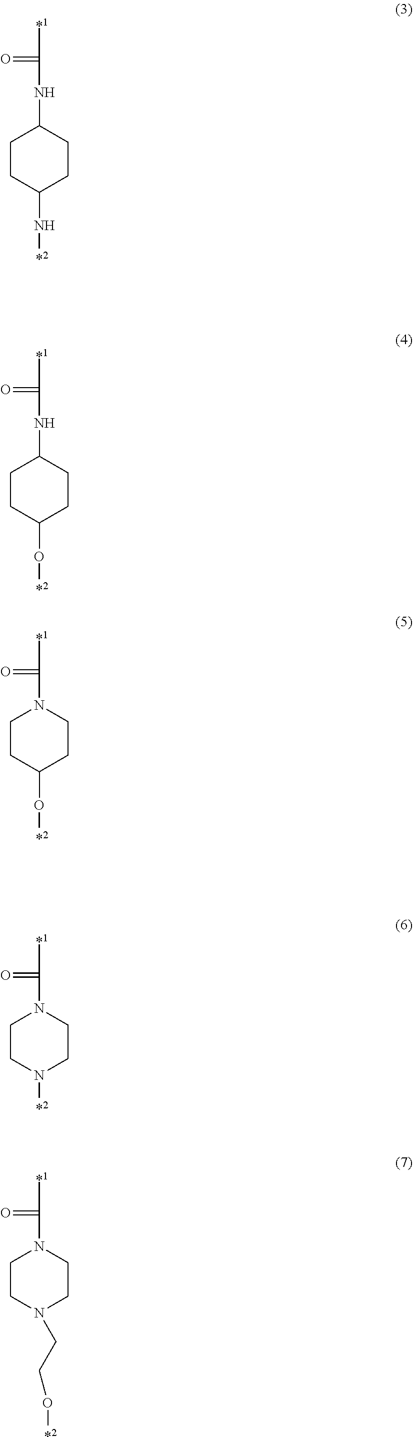

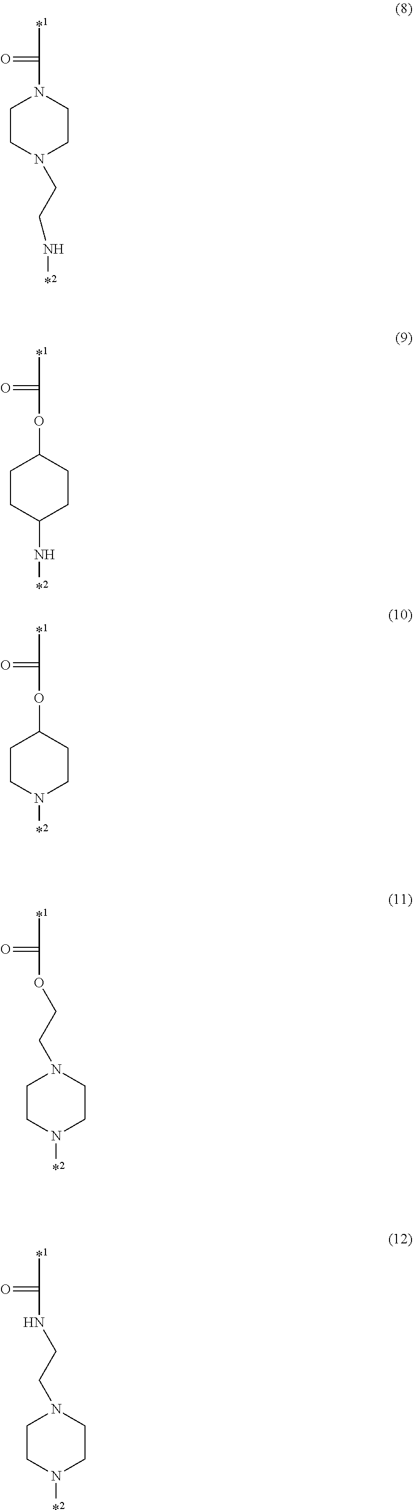

In Formulae (3) to (12), *1 represents a bonding position between R¹ in Formula (A) and a carbon atom bonded thereto, and *2 represents a bonding position with A in Formula (A).

Among the divalent linking groups each represented by any one of Formula (3), . . . , or Formula (12), a divalent linking group represented by any one of Formula (4), Formula (5), Formula (9), or Formula (10) is preferable since the balance between the solubility in a solvent to be used during the formation of the second optically anisotropic layer and the solvent resistance of the second optically anisotropic layer to be obtained is improved.

Next, the photo-alignment group represented by A in Formula (A) will be described.

Since the thermal stability and chemical stability of a monomer having a photo-alignment group are improved, the photo-alignment group is preferably a group in which at least one of dimerization or isomerization is caused by the action of light.

Specific suitable examples of the group which is dimerized by the action of light include groups having a skeleton of at least one derivative selected from the group consisting of a cinnamic acid derivative, a coumarin derivative, a chalcone derivative, a maleimide derivative, and a benzophenone derivative.

Specific suitable examples of the group which is isomerized by the action of light include groups having a skeleton of at least one compound selected from the group consisting of an azobenzene compound, a stilbene compound, a spiropyran compound, a cinnamic acid compound, and a hydrazono-β-ketoester compound.

Among such photo-alignment groups, groups having a skeleton of at least one derivative or compound selected from the group consisting of a cinnamic acid derivative, a coumarin derivative, a chalcone derivative, a maleimide derivative, an azobenzene compound, a stilbene compound, and a spiropyran compound are preferable. Among these, since the liquid crystal alignment properties of the first optically anisotropic layer are improved, groups having a skeleton of a cinnamic acid derivative or an azobenzene compound are more preferable, and groups having a skeleton of a cinnamic acid derivative (hereinafter, also abbreviated as “cinnamoyl group”) are even more preferable.

In the present invention, the photo-alignment group is preferably a photo-alignment group represented by Formula (a2).

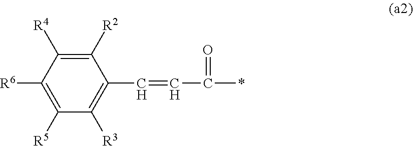

In Formula (a2), * represents a bonding position with L¹, R² to R⁶ each independently represent a hydrogen atom or a substituent, and two adjacent groups may be bonded to form a ring.

Here, since the liquid crystal alignment properties of the first optically anisotropic layer are improved, the substituents represented by one aspect of R² to R⁶ each independently preferably represent a halogen atom, a linear alkyl group having 1 to 20 carbon atoms, a branched or cyclic alkyl group having 3 to 20 carbon atoms, a linear halogenated alkyl group having 1 to 20 carbon atoms, an alkoxy group having 1 to 20 carbon atoms, an aryl group having 6 to 20 carbon atoms, an aryloxy group having 6 to 20 carbon atoms, a hydroxy group, a cyano group, an amino group, or a group represented by Formula (a3).

Specific examples of the substituents other than the group represented by Formula (a3) include the same ones as those described for the substituent represented by one aspect of R¹ in Formula (A).

In addition, the substituent may contain a linking group represented by —(CH₂)ₙₐ— or —O—(CH₂)ₙₐ—. na represents an integer of 1 to 10.

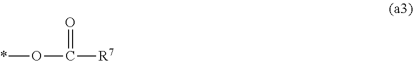

Here, in Formula (a3), * represents a bonding position with a benzene ring in Formula (a2), and R⁷ represents a monovalent organic group.

Examples of the monovalent organic group represented by R⁷ in Formula (a3) include an alkyl group having 1 to 20 carbon atoms, and examples thereof include a linear alkyl group having 1 to 20 carbon atoms and a cyclic alkyl group having 3 to 20 carbon atoms.

The linear alkyl group is preferably an alkyl group having 1 to 6 carbon atoms, and specific examples thereof include a methyl group, an ethyl group, and an n-propyl group. Among these, a methyl group or an ethyl group is preferable.

The cyclic alkyl group is preferably an alkyl group having 3 to 6 carbon atoms, and specific examples thereof include a cyclopropyl group, a cyclopentyl group, and a cyclohexyl group. Among these, a cyclohexyl group is preferable.

The monovalent organic group represented by R⁷ in Formula (a3) may be obtained by combining the linear alkyl group and the cyclic alkyl group described above directly or via a single bond.

In the present invention, since the liquid crystal alignment properties of the first optically anisotropic layer are improved, at least one (particularly, R⁶) of R², . . . , or R⁶ in Formula (a2) is preferably the above-described substituent. Since the linearity of the photo-alignment polymer to be obtained is improved and the reaction efficiency is improved during polarized light irradiation, at least one (particularly, R⁶) of R², . . . , or R⁶ in Formula (a2) is more preferably an electron-donating substituent.

Here, the electron-donating substituent (electron-donating group) refers to a substituent having a Hammett constant (Hammett substituent constant σp) of 0 or less, and an alkyl group, a halogenated alkyl group, an alkoxy group, and the like are exemplified among the above-described substituents.

Among these, an alkoxy group is preferable. Since the liquid crystal alignment properties of the adjacent liquid crystal layer are further improved, an alkoxy group having 6 to 16 carbon atoms is more preferable, and an alkoxy group having 7 to 10 carbon atoms is even more preferable.

Examples of the repeating unit A represented by Formula (A) include the repeating units described in paragraph [0046] in WO2019/225632A and the following repeating units A-45 to A-56.

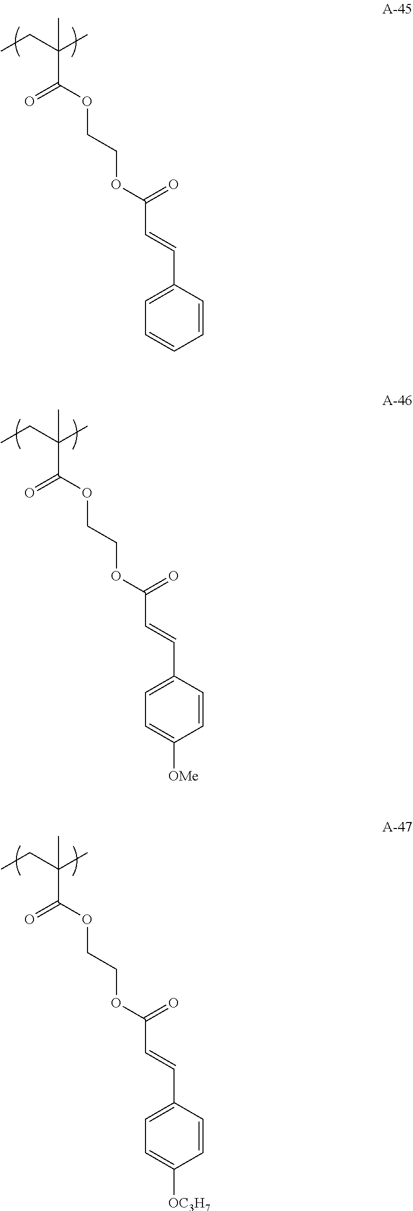

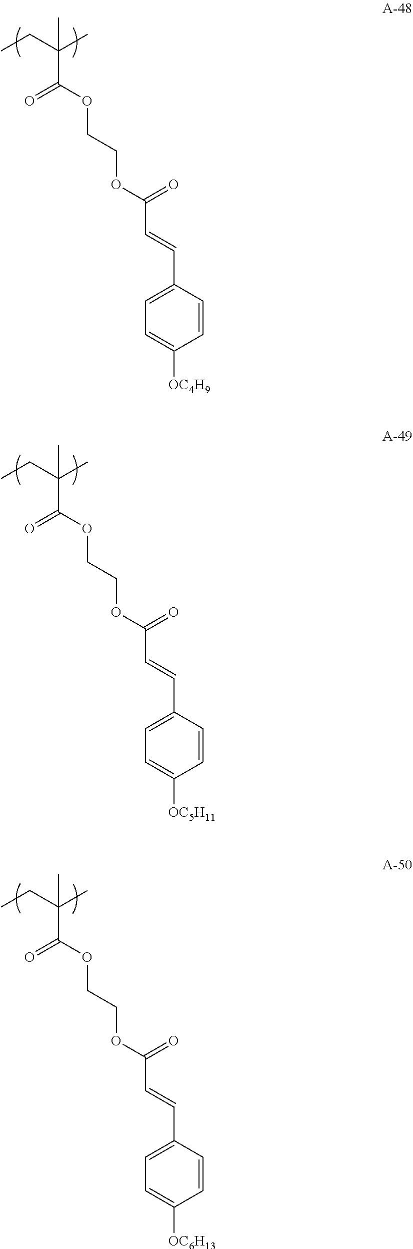

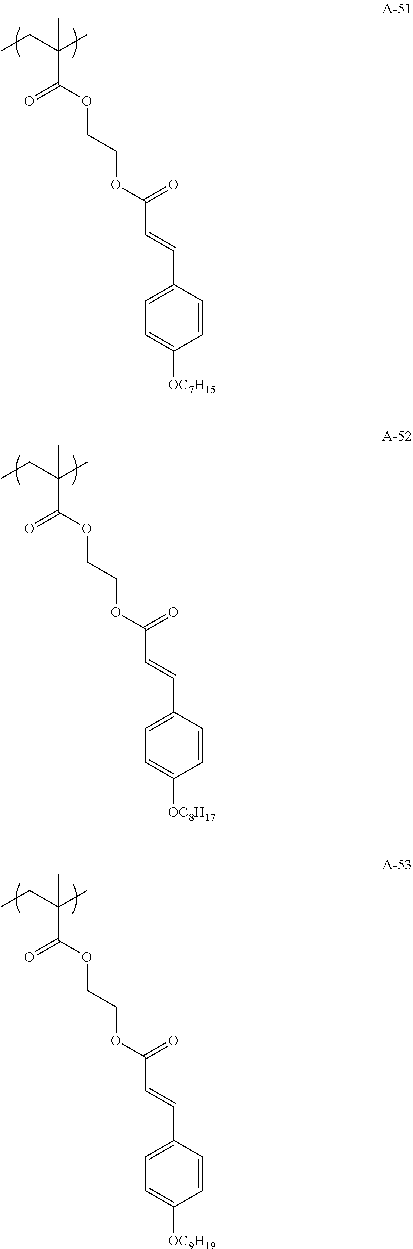

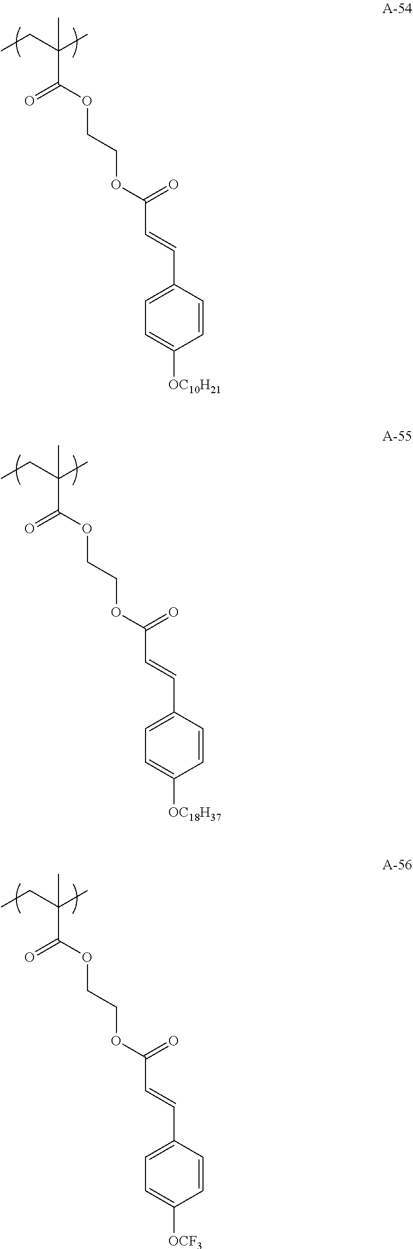

The content of the repeating unit containing a photo-alignment group in the photo-alignment polymer of the present invention is not particularly limited, and is preferably 3 to 40 mass %, more preferably 6 to 30 mass %, and even more preferably 10 to 25 mass % with respect to all the repeating units of the photo-alignment polymer since the liquid crystal alignment properties of the first optically anisotropic layer are improved.

(Repeating Unit Containing Hydroxyl Group)

Examples of the repeating unit containing a hydroxyl group among the repeating units containing a polar group include a repeating unit represented by Formula (B) (hereinafter, also abbreviated as “repeating unit B”).

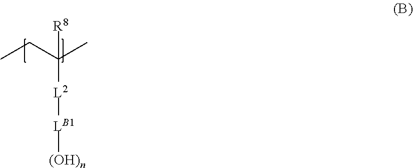

In Formula (B), R⁸ represents a hydrogen atom or a substituent. Examples of the substituent represented by one aspect of R⁸ include the same ones as those described for the substituent represented by one aspect of R¹ in Formula (A).

In addition, in Formula (B), L² represents a divalent linking group. Examples of the divalent linking group represented by L² include the same ones as those described for the divalent linking group represented by L¹ in Formula (A).

In addition, in Formula (B), n represents an integer of 1 or more, and since the liquid crystal alignment properties of the first optically anisotropic layer are improved, n is preferably an integer of 1 to 10, more preferably an integer of 1 to 5, and even more preferably an integer of 1 to 3.

In addition, in Formula (B), L^{B1} represents an n+1-valent linking group.

In the present invention, since the liquid crystal alignment properties of the first optically anisotropic layer are improved, L^{B1} in Formula (B) preferably represents an n+1-valent aliphatic hydrocarbon group having one or more carbon atoms.

Here, the aliphatic hydrocarbon group is n+1-valent. Therefore, for example, in a case where n is 1, the aliphatic hydrocarbon group is a divalent aliphatic hydrocarbon group (so-called alkylene group), in a case where n is 2, the aliphatic hydrocarbon group is a trivalent aliphatic hydrocarbon group, and in a case where n is 3, the aliphatic hydrocarbon group is a tetravalent aliphatic hydrocarbon group.

In addition, the aliphatic hydrocarbon group may have any one of a linear structure, a branched structure, or a cyclic structure.

The number of carbon atoms contained in the n+1-valent linking group is not particularly limited, and is preferably 1 to 24, and more preferably 1 to 10.

Examples of the repeating unit B represented by Formula (B) include the following repeating units B-1 to B-4.

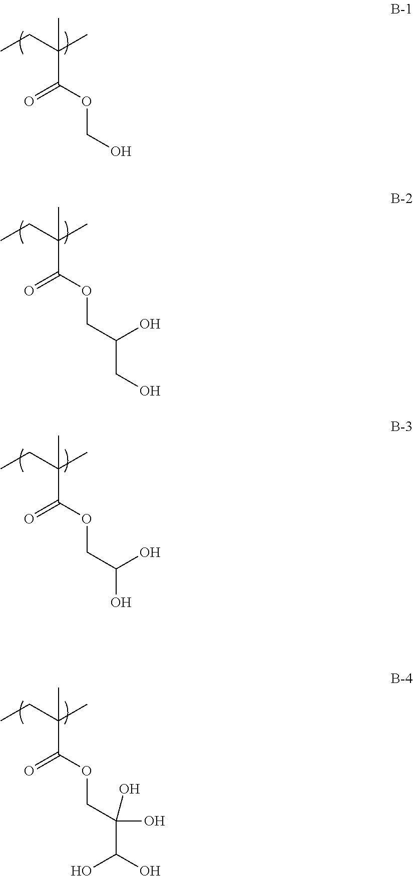

(Repeating Unit Containing Ketone Group)

Examples of the repeating unit containing a ketone group among the repeating units containing a polar group include a repeating unit represented by Formula (C) (hereinafter, also abbreviated as “repeating unit C”).

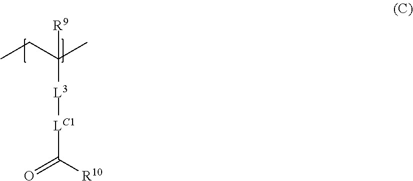

In Formula (C), R⁹ represents a hydrogen atom or a substituent. Examples of the substituent represented by one aspect of R⁹ include the same ones as those described for the substituent represented by one aspect of R¹ in Formula (A).

In addition, in Formula (C), L³ represents a divalent linking group. Examples of the divalent linking group represented by L³ include the same ones as those described for the divalent linking group represented by L¹ in Formula (A).

In addition, in Formula (C), L^{C1} represents an n+1-valent linking group. Examples of the n+1-valent linking group represented by L^{C1} include the same ones as those described for the n+1-valent linking group represented by L^{B1} in Formula (B).

In addition, in Formula (C), R¹⁰ represents an alkyl group having 1 to 6 carbon atoms, and is preferably a methyl group.

Examples of the repeating unit C represented by Formula (C) include the following repeating unit C-1.

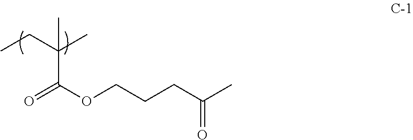

The content of the repeating unit containing a polar group in the photo-alignment polymer of the present invention is not particularly limited, and is preferably 5 mol % or greater, more preferably 10 mol % or greater, even more preferably 15 mol % or greater, particularly preferably 20 mol % or greater, preferably 90 mol % or less, more preferably 70 mol % or less, even more preferably 50 mol % or less, particularly preferably 40 mol % or less, and most preferably 35 mol % or less with respect to all the repeating units of the photo-alignment polymer since the liquid crystal alignment properties of the first optically anisotropic layer are improved.

The photo-alignment polymer of the present invention may have a repeating unit other than the above-described repeating units.

Examples of the monomer (radically polymerizable monomer) forming a repeating unit other than the above repeating units include an acrylic acid ester compound, a methacrylic acid ester compound, a maleimide compound, an acrylamide compound, acrylonitrile, maleic anhydride, a styrene compound, and a vinyl compound.

The method of synthesizing the photo-alignment polymer of the present invention is not particularly limited. For example, the photo-alignment polymer can be synthesized by mixing a monomer forming the repeating unit containing a photo-alignment group described above, a monomer forming the repeating unit containing a polar group described above, and monomers forming other optional repeating units, and polymerizing the monomers using a radical polymerization initiator in an organic solvent.

The weight-average molecular weight (Mw) of the photo-alignment polymer of the present invention is not particularly limited, and is preferably 10,000 to 500,000, more preferably 10,000 to 300,000, and even more preferably 30,000 to 150,000.

Here, in the present invention, the weight-average molecular weight and the number-average molecular weight are values measured by gel permeation chromatography (GPC) under the following conditions.
Solvent (eluent): Tetrahydrofuran (THF)
Device Name: TOSOH HLC-8320GPC
Column: Three items of TOSOH TSKgel Super HZM-H (4.6 mm×15 cm) are connected and used.
Column Temperature: 40° C.
Sample Concentration: 0.1 mass %
Flow Rate: 1.0 ml/min
Calibration Curve: A calibration curve made by 7 samples of TSK standard polystyrene manufactured by TOSOH Corporation, Mw of which is 2,800,000 to 1,050 (Mw/Mn=1.03 to 1.06), is used.

<Liquid Crystal Composition>

The second optically anisotropic layer having the photo-alignment polymer of the present invention in a surface layer A is an optically anisotropic layer consisting of a liquid crystal layer.

Therefore, the second optically anisotropic layer is preferably formed of, for example, a liquid crystal composition (hereinafter, also abbreviated as “optically anisotropic layer forming composition”) containing: a photo-alignment polymer (hereinafter, also abbreviated as “cleavage group-containing photo-alignment polymer”) having a repeating unit containing a cleavage group which is decomposed by the action of at least one selected from the group consisting of light, heat, acid, and base to produce a polar group; and a liquid crystal compound.

(Cleavage Group-Containing Photo-Alignment Polymer)

Examples of the cleavage group-containing photo-alignment polymer contained in the optically anisotropic layer forming composition include a polymer which produces a repeating unit (repeating unit B) represented by Formula (B) by the action of an acid and has a repeating unit having a group represented by Formula (1), and a polymer which produces a repeating unit (repeating unit C) represented by Formula (C) by the action of an acid and has a repeating unit having a group represented by Formula (2).

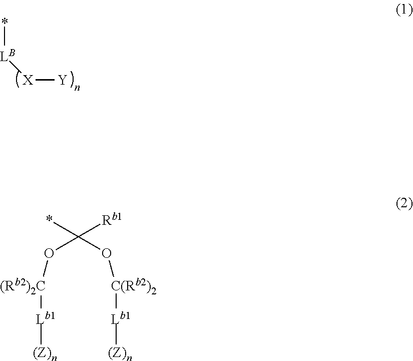

In Formula (1),

L^{B} is the same as L^{B1} in Formula (B).

X represents a cleavage group which is decomposed by the action of an acid to produce a hydroxyl group.

Y represents a group containing a fluorine atom or a silicon atom.

n represents an integer of 1 or more.

* represents a bonding position.

In addition, in Formula (2),

R^{b1} and R^{b2} each represent a hydrogen atom or a substituent.

L^{b1} represents an n+1-valent linking group. A plurality of L^{b1}'s may be the same or different from each other.

Z represents an aliphatic hydrocarbon group having a fluorine atom or an organosiloxane group. The aliphatic hydrocarbon group may have an oxygen atom, and a plurality of Z's may be the same or different from each other.

Examples of the cleavage group represented by X include cleavage groups represented by Formulae (B1) to (B5).

* in Formulae (B1) to (B5) represents a bonding position.

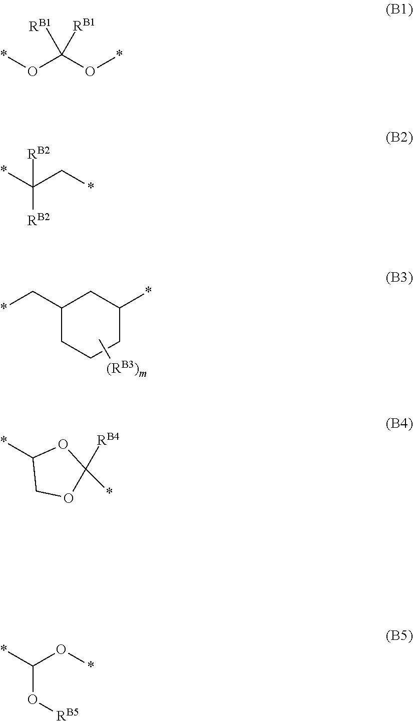

In Formula (B1), R^{B1}'s each independently represent a hydrogen atom or a substituent. At least one of the two R^{B1}'s represents a substituent, and the two R^{B1}'s may be bonded to each other to form a ring.

In Formula (B2), R^{B2}'s each independently represent a substituent. The two R^{B2}'s may be bonded to each other to form a ring.

In Formula (B3), R^{B3} represents a substituent, and m represents an integer of 0 to 3.

In a case where m is 2 or 3, a plurality of R^{B3} may be the same or different from each other.

In Formula (B4), R^{B4} represents a hydrogen atom or a substituent.

In Formula (B5), R^{B5} represents a substituent.

n represents an integer of 1 or more. In the above range, the integer is preferably 1 to 10, more preferably 1 to 5, and even more preferably 1 to 3 since the liquid crystal alignment properties are improved.

Specific examples of the repeating unit having a group represented by Formula (1) include repeating units represented by Formulae 1-B to 9-B, and specific examples of the repeating unit having a group represented by Formula (λ) include a repeating unit represented by Formula 1-C.

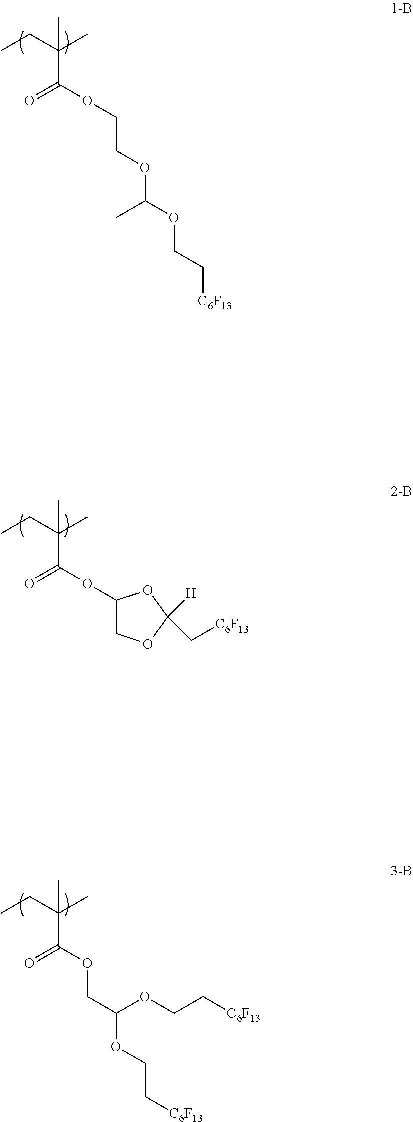

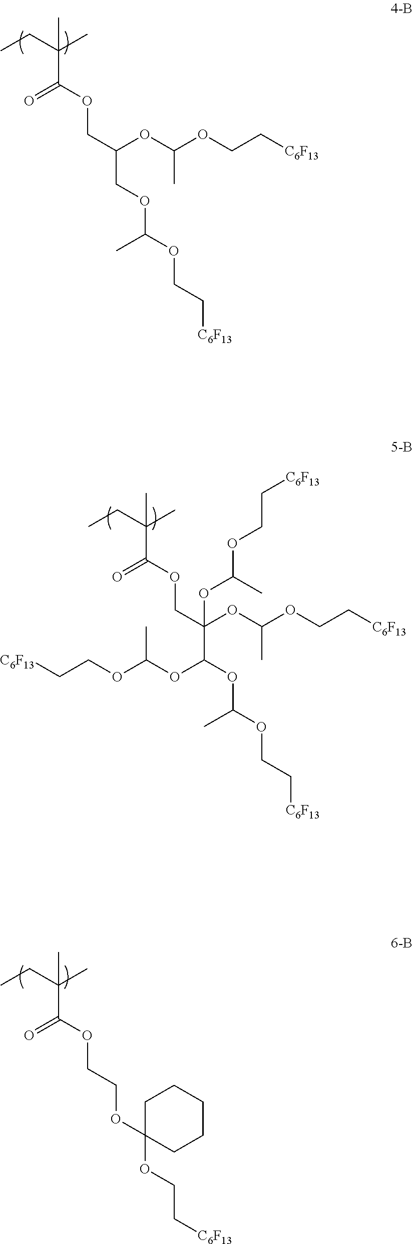

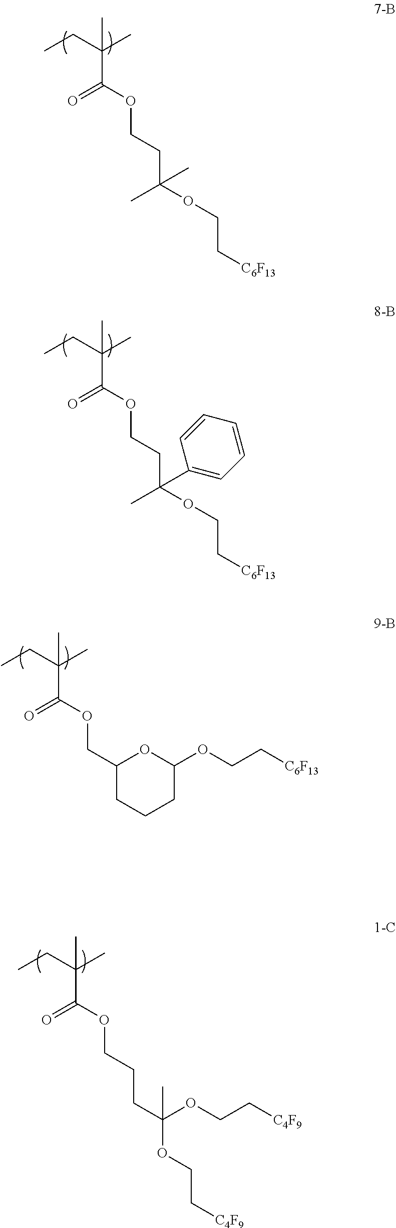

(Liquid Crystal Compound)

The liquid crystal compound contained in the optically anisotropic layer forming composition is a liquid crystal compound having a polymerizable group.

In general, liquid crystal compounds can be classified into a rod-like type and a disk-like type according to the shape thereof. Furthermore, each type includes a low molecular type and a high molecular type. The term high molecular generally refers to a compound having a degree of polymerization of 100 or greater (Polymer Physics-Phase Transition Dynamics, written by Masao Doi, p. 2, published by Iwanami Shoten, 1992).

In the present invention, any liquid crystal compound can be used, but a rod-like liquid crystal compound or a discotic liquid crystal compound is preferably used, and a rod-like liquid crystal compound is more preferably used.

In the present invention, in order to fix the above-described liquid crystal compound, a liquid crystal compound having a polymerizable group is used, and it is further preferable that the liquid crystal compound has two or more polymerizable groups in one molecule. In a case where a mixture of two or more types of liquid crystal compounds is used, at least one liquid crystal compound preferably has two or more polymerizable groups in one molecule. After fixing of the liquid crystal compound by polymerization, it is no longer necessary for the compound to exhibit crystallinity.

The type of the polymerizable group is not particularly limited. A functional group allowing an addition polymerization reaction is preferable, and a polymerizable ethylenically unsaturated group or a cyclic polymerizable group is preferable. More specifically, preferable examples thereof include a (meth)acryloyl group, a vinyl group, a styryl group, and an allyl group, and a (meth)acryloyl group is more preferable. A (meth)acryloyl group is a concept referring to a methacryloyl group or an acryloyl group.

As the rod-like liquid crystal compound, for example, those described in claim 1 in JP1999-513019A (JP-H11-513019A) or paragraphs [0026] to [0098] in JP2005-289980A can be preferably used, and as the discotic liquid crystal compound, for example, those described in paragraphs [0020] to [0067] in JP2007-108732A or paragraphs [0013] to [0108] in JP2010-244038A can be preferably used. However, the compounds are not limited thereto.

In the present invention, as the liquid crystal compound, a liquid crystal compound having reverse wavelength dispersibility can be used.

Here, in this specification, the liquid crystal compound having “reverse wavelength dispersibility” refers to the fact that in the measurement of an in-plane retardation (Re) value at a specific wavelength (visible light range) of a retardation film produced using the liquid crystal compound, as the measurement wavelength increases, the Re value is the same or increased.

The liquid crystal compound having reverse wavelength dispersibility is not particularly limited as long as a film having reverse wavelength dispersibility can be formed as described above, and examples thereof include the compounds represented by General Formula (1) described in JP2010-084032A (particularly, the compounds described in paragraphs [0067] to [0073]), the compounds represented by General Formula (II) described in JP2016-053709A (particularly, the compounds described in paragraphs [0036] to [0043]), and the compounds represented by General Formula (1) described in JP2016-081035A (particularly, the compounds described in paragraphs [0043] to [0055]).

The state in which the liquid crystal compound is aligned (alignment state) is not particularly limited, and examples thereof include known alignment states. Examples of the alignment state include homogeneous alignment and homeotropic alignment. More specifically, in a case where the liquid crystal compound is a rod-like liquid crystal compound, examples of the alignment state include nematic alignment (a state in which a nematic phase is formed), smectic alignment (a state in which a smectic phase is formed), cholesteric alignment (a state in which a cholesteric phase is formed), and hybrid alignment. In a case where the liquid crystal compound is a discotic liquid crystal compound, examples of the alignment state include nematic alignment, columnar alignment (a state in which a columnar phase is formed), and cholesteric alignment.

(Photo-Acid Generator)

The optically anisotropic layer forming composition preferably contains a photo-acid generator.

The photo-acid generator is not particularly limited, and is preferably a compound which is sensitive to actinic rays having a wavelength of 300 nm or greater, preferably 300 to 450 nm, and generates an acid. A photo-acid generator which is not directly sensitive to actinic rays having a wavelength of 300 nm or greater can also be preferably used in combination with a sensitizer as long as it is a compound which is sensitive to actinic rays having a wavelength of 300 nm or greater and generates an acid by being used in combination with the sensitizer.

The photo-acid generator is preferably a photo-acid generator which generates an acid with a pKa of 4 or less, more preferably a photo-acid generator which generates an acid with a pKa of 3 or less, and even more preferably a photo-acid generator which generates an acid with a pKa of 2 or less. In the present invention, the pKa basically refers to a pKa in water at 25° C. Those which cannot be measured in water refer to those measured after changing to a solvent suitable for the measurement. Specifically, the pKa described in a chemical handbook or the like can be referred to. The acid with a pKa of 3 or less is preferably a sulfonic acid or a phosphonic acid, and more preferably a sulfonic acid.

Examples of the photo-acid generator include an onium salt compound, trichloromethyl-s-triazines, a sulfonium salt, an iodonium salt, quaternary ammonium salts, a diazomethane compound, an imidosulfonate compound, and an oxime sulfonate compound. Among these, an onium salt compound, an imidosulfonate compound, or an oxime sulfonate compound is preferable, and an onium salt compound or an oxime sulfonate compound is more preferable. The photo-acid generators can be used alone or in combination of two or more types thereof.

(Polymerization Initiator)

The optically anisotropic layer forming composition preferably contains a polymerization initiator.

The polymerization initiator is not particularly limited, and examples thereof include a thermal polymerization initiator and a photopolymerization initiator depending on the method of a polymerization reaction.

The polymerization initiator is preferably a photopolymerization initiator capable of initiating a polymerization reaction by ultraviolet irradiation.

Examples of the photopolymerization initiator include α-carbonyl compounds (described in U.S. Pat. Nos. 2,367,661A and 2,367,670A), acyloin ethers (described in U.S. Pat. No. 2,448,828A), a-hydrocarbon-substituted aromatic acyloin compounds (described in U.S. Pat. No. 2,722,512A), polynuclear quinone compounds (described in U.S. Pat. Nos. 3,046,127A and 2,951,758A), combinations of triarylimidazole dimer and p-aminophenyl ketone (described in U.S. Pat. No. 3,549,367A), acridine and phenazine compounds (described in JP1985-105667A (JP-S60-105667A) and U.S. Pat. No. 4,239,850A), oxadiazole compounds (described in U.S. Pat. No. 4,212,970A), and acylphosphine oxide compounds (described in JP1988-040799B (JP-S63-040799B), JP1993-029234B (JP-H05-029234B), JP1998-095788A (JP-H10-095788A), and JP1998-029997A (JP-H10-029997A)).

(Solvent)

The optically anisotropic layer forming composition preferably contains a solvent from the viewpoint of workability.

Examples of the solvent include ketones (for example, acetone, 2-butanone, methyl isobutyl ketone, cyclopentanone, and cyclohexanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide).

The solvents may be used alone or in combination of two or more types thereof.

(Other Components)

The optically anisotropic layer forming composition may contain a component other than the above components. For example, a crosslinking agent, a surfactant, a hydrophilic compound, a vertical alignment agent, a horizontal alignment agent, an amine compound, and the like may be contained.

Examples of the crosslinking agent include a compound having an epoxy group or an oxetanyl group, a blocked isocyanate compound, and an alkoxymethyl group-containing compound.

Examples of the surfactant include compounds which have been known. Examples thereof include a surfactant having a fluorine atom and a surfactant having a silicon atom. In the present invention, from the viewpoint of not inhibiting the direct lamination of the second optically anisotropic layer and the first optically anisotropic layer, the optically anisotropic layer forming composition for forming an optically anisotropic layer which is positioned as a lower layer of the optical laminate preferably does not contain a surfactant having a fluorine atom or a surfactant having a silicon atom, and more preferably does not contain both the surfactant having a fluorine atom and the surfactant having a silicon atom. In a case where the optical laminate is formed in this way, it is possible to obtain an optical laminate in which fluorine or silicon is substantially not present in the surface of the second optically anisotropic layer on the side in contact with the first optically anisotropic layer. In a case where the surfactant is contained, the content thereof is preferably 0.01 to 5 mass %, and more preferably 0.05 to 3 mass % with respect to the liquid crystal compound.

The hydrophilic compound is preferably a compound capable of fixing the alignment of the liquid crystal compound in a vertical direction, and examples thereof include the polymer compounds described in paragraphs [0042] to [0046] in JP6739535B. The content of the hydrophilic compound is preferably 0.5 to 10 mass % with respect to the liquid crystal compound contained in the optically anisotropic layer forming composition. The vertical alignment agent may have a function of promoting the vertical alignment of the liquid crystal compound. Examples thereof include an ionic compound and a boronic acid compound. The content of the vertical alignment agent is preferably 0.1 to 5 mass %, and more preferably 0.5 to 3 mass % with respect to the liquid crystal compound. Only one type of vertical alignment agent, or two or more types of vertical alignment agents may be contained. In a case where two or more types are contained, the total amount thereof is preferably within the above range.

The horizontal alignment agent may have a function of promoting the horizontal alignment of the liquid crystal compound. The content of the horizontal alignment agent is preferably 0.1 to 5 mass % with respect to the liquid crystal compound.

The amine compound may have a function of not deteriorating the aligning properties of the liquid crystal compound in a case where the optically anisotropic layer forming composition is stored for several days (for example, about one week) after being prepared. As such an amine compound, an amine compound having a boiling point of 50° C. to 230° C. and having no proton on the nitrogen atom is preferable, secondary amine and tertiary amine are more preferable, and diisopropylethylamine and tributylamine are particularly preferable. The content of the amine compound is preferably 0.01 to 10 mass % with respect to the liquid crystal compound.

The second optically anisotropic layer of the optical laminate according to the embodiment of the present invention is preferably a layer which is formed of the above-described optically anisotropic layer forming composition, and whose surface has alignment controllability. More specifically, the second optically anisotropic layer is preferably a layer formed by generating an acid from the photo-acid generator in a coating film of the optically anisotropic layer forming composition and then performing a photo-alignment treatment.

That is, in the method of forming the second optically anisotropic layer, it is preferable that a curing treatment is performed on a coating film formed of the optically anisotropic layer forming composition, a treatment for generating an acid from the photo-acid generator in the coating film (hereinafter, also simply referred to as “acid generation treatment”) is performed, and then a photo-alignment treatment is performed to form the second optically anisotropic layer.

As will be described later, the curing treatment and the acid generation treatment may be performed at the same time.

Hereinafter, the method of performing the curing treatment will be described in detail.

The method of forming a coating film of the optically anisotropic layer forming composition is not particularly limited, and examples thereof include a method including performing coating with the optically anisotropic layer forming composition on a support and optionally performing a drying treatment.

Examples of the support include a glass substrate and a polymer film.

Examples of the material of the polymer film include cellulose-based polymers; acrylic polymers having an acrylic acid ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer; polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

In addition, an alignment layer may be disposed on the support.

In addition, the support may be peeled off after formation of the optical laminate.

The thickness of the support is not particularly limited, and is preferably 5 to 200 μm, more preferably 10 to 100 μm, and even more preferably 20 to 90 μm.

The method of performing coating with the optically anisotropic layer forming composition is not particularly limited, and examples of the coating method include a spin coating method, an air knife coating method, a curtain coating method, a roller coating method, a wire bar coating method, a gravure coating method, and a die coating method.

Next, the curing treatment and the acid generation treatment are performed on the coating film of the optically anisotropic layer forming composition.

Examples of the curing treatment include a light irradiation treatment and a heating treatment.

The conditions of the curing treatment are not particularly limited, and ultraviolet rays are preferably used in polymerization by light irradiation. The irradiation dose is preferably 10 mJ/cm² to 50 J/cm², more preferably 20 mJ/cm² to 5 J/cm², even more preferably 30 mJ/cm² to 3 J/cm², and particularly preferably 50 to 1,000 mJ/cm². In order to promote the polymerization reaction, the treatment may be performed under heating conditions.

The treatment for generating an acid from the photo-acid generator in the coating film is a treatment for generating an acid by irradiation with light to which the photo-acid generator contained in the optically anisotropic layer forming composition is exposed. By performing the treatment, cleavage at the cleavage group proceeds, and the group containing a fluorine atom or a silicon atom is eliminated.

The light irradiation treatment performed in the above treatment may be a treatment in which the photo-acid generator is exposed to light, and examples thereof include an ultraviolet irradiation method. As a light source, a lamp emitting ultraviolet rays, such as a high-pressure mercury lamp and a metal halide lamp, can be used. In addition, the irradiation dose is preferably 10 mJ/cm² to 50 J/cm², more preferably 20 mJ/cm² to 5 J/cm², even more preferably 30 mJ/cm² to 3 J/cm², and particularly preferably 50 to 1,000 mJ/cm².

Regarding the curing treatment and the acid generation treatment, the acid generation treatment may be performed after the curing treatment, or the curing treatment and the acid generation treatment may be performed at the same time. In particular, in a case where the photo-acid generator and the polymerization initiator in the optically anisotropic layer forming composition are exposed to light of the same wavelength, it is preferable that the curing treatment and the acid generation treatment are performed at the same time from the viewpoint of productivity.

The method for the photo-alignment treatment to be performed on the coating film of the optically anisotropic layer forming composition formed as described above (including the cured film of the optically anisotropic layer forming composition subjected to the curing treatment) is not particularly limited, and examples thereof include known methods.

Examples of the photo-alignment treatment include a method of irradiating the coating film of the optically anisotropic layer forming composition (including the cured film of the optically anisotropic layer forming composition subjected to the curing treatment) with polarized light or irradiating the surface of the coating film with unpolarized light from an oblique direction.

In the photo-alignment treatment, the polarized light to be applied is not particularly limited. Examples thereof include linearly polarized light, circularly polarized light, and elliptically polarized light, and linearly polarized light is preferable.

In addition, the “oblique direction” in which irradiation with unpolarized light is performed is not particularly limited as long as it is a direction inclined at a polar angle θ (0°<θ<90°) with respect to a normal direction of the surface of the coating film. θ can be appropriately selected according to the purpose, and is preferably 20° to 80°.

The wavelength of the polarized light or the unpolarized light is not particularly limited as long as the light is light to which the photo-alignment group is exposed. Examples thereof include ultraviolet rays, near-ultraviolet rays, and visible rays, and near-ultraviolet rays of 250 to 450 nm are preferable.

In addition, examples of the light source for the irradiation with polarized light or unpolarized light include a xenon lamp, a high-pressure mercury lamp, an extra-high-pressure mercury lamp, and a metal halide lamp. By using an interference filter, a color filter, or the like with respect to ultraviolet rays or visible rays obtained from the light source, the wavelength range of the irradiation can be restricted. In addition, linearly polarized light can be obtained by using a polarization filter or a polarization prism with respect to the light from the light source.

The integrated quantity of the polarized light or the unpolarized light is not particularly limited, and is preferably 1 to 300 mJ/cm², and more preferably 5 to 100 mJ/cm².

The illuminance of the polarized light or the unpolarized light is not particularly limited, and is preferably 0.1 to 300 mW/cm², and more preferably 1 to 100 mW/cm².

An aspect has been described in which the curing treatment and the acid generation treatment are performed before the photo-alignment treatment, but the present invention is not limited to this aspect. The curing treatment and the acid generation treatment may be performed at the same time in the photo-alignment treatment.

The method of forming the second optically anisotropic layer described above can be applied regardless of whether the second optically anisotropic layer is a positive C plate or a positive A plate, and in a case where the second optically anisotropic layer is a positive A plate, it is preferably formed by the following method.

First, even in a case where the second optically anisotropic layer is a positive A plate, the above-described support is coated with the optically anisotropic layer forming composition by the above-described method.

Next, a crosslinking treatment of the cleavage group-containing photo-alignment polymer in the optically anisotropic layer coating film is performed.

Examples of the crosslinking treatment include a light irradiation treatment and a heating treatment.

In addition, the cleavage group-containing photo-alignment polymer used may have a repeating unit having a crosslinkable group to be described later, and an optimum treatment is selected according to the type of the crosslinkable group. For example, in a case where the crosslinkable group in the cleavage group-containing photo-alignment polymer reacts by the action of an acid, examples of the crosslinking treatment include an acid generation treatment.

The crosslinking treatment is preferably an acid generation treatment from the viewpoint of productivity and ease of reaction of the crosslinkable group.

The acid generation treatment is a treatment for generating an acid from the photo-acid generator or thermal acid generator in the coating film. Specifically, the acid generation treatment is a treatment (light irradiation treatment) for generating an acid by applying light to which the photo-acid generator contained in the coating film is exposed, or a treatment (heat treatment) for generating an acid by applying heat. By performing this treatment, the crosslinkable group reacts and is crosslinked.

The light irradiation treatment performed in the above treatment may be a treatment in which the photo-acid generator is exposed to light, and examples thereof include an ultraviolet irradiation method. As a light source, a lamp emitting ultraviolet rays, such as a high-pressure mercury lamp and a metal halide lamp, can be used. In addition, the irradiation dose is preferably 10 mJ/cm² to 50 J/cm², more preferably 20 mJ/cm² to 5 J/cm², even more preferably 30 mJ/cm² to 3 J/cm², and particularly preferably 50 to 1,000 mJ/cm².

The heat treatment performed in the above treatment may be a treatment in which the thermal acid generator is cleaved. The temperature is preferably 50° C. or higher, more preferably 80° C. or higher, and particularly preferably 110° C. or higher.

Next, the photo-alignment treatment and the curing treatment are performed by the above-described method.

An aspect has been described in which the crosslinking treatment and the acid generation treatment are performed at the same time before the photo-alignment treatment, but the present invention is not limited to this aspect. The acid generation treatment may be performed after the photo-alignment treatment.

(Repeating Unit Having Crosslinkable Group)

Examples of the above-described repeating unit having a crosslinkable group include a polymer having a repeating unit having a crosslinkable group that causes a polymerization reaction by the action of an acid.

The type of the crosslinkable group is not particularly limited, and examples thereof include known crosslinkable groups. The crosslinkable group is preferably a cationically polymerizable group or a radically polymerizable group from the viewpoint of excellent adhesiveness between the first optically anisotropic layer and the second optically anisotropic layer.

Examples of the cationically polymerizable group include an epoxy group, an epoxycyclohexyl group, and an oxetanyl group.

Examples of the radically polymerizable group include an acryloyl group, a methacryloyl group, a vinyl group, a styryl group, and an allyl group.

The structure of a main chain of the repeating unit containing a crosslinkable group is not particularly limited, and examples thereof include known structures. For example, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable. Among these, a skeleton selected from the group consisting of a (meth)acrylic skeleton, a siloxane-based skeleton, and a cycloolefin-based skeleton is more preferable, and a (meth)acrylic skeleton is even more preferable.

Specific examples of the repeating unit containing a crosslinkable group include the following repeating units.

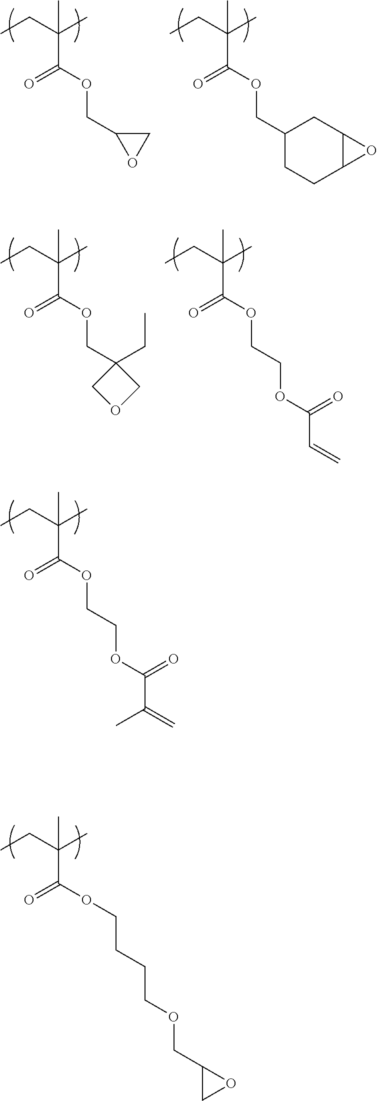

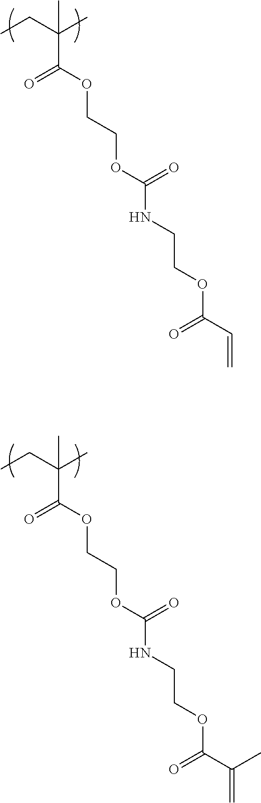

The thickness of the second optically anisotropic layer is not particularly limited, and is preferably 0.1 to 10 μm, more preferably 0.2 to 5 μm, and even more preferably 0.3 to 2 μm since the liquid crystal alignment properties of the first optically anisotropic layer are improved.

[First Optically Anisotropic Layer]

The first optically anisotropic layer of the optical laminate according to the embodiment of the present invention is an optically anisotropic layer consisting of a liquid crystal layer which is directly laminated on the above-described second optically anisotropic layer.

The first optically anisotropic layer is preferably formed of a liquid crystal composition containing a liquid crystal compound.

Here, examples of the liquid crystal composition for forming the first optically anisotropic layer include a composition obtained by blending the liquid crystal compound, the polymerization initiator, the solvent, and the like described in the description of the optically anisotropic layer forming composition.

Examples of the method of forming the first optically anisotropic layer include a method of directly coating the above-described second optically anisotropic layer with a liquid crystal composition containing a liquid crystal compound.

Here, the coating method is not particularly limited, and examples of the coating method include a spin coating method, an air knife coating method, a curtain coating method, a roller coating method, a wire bar coating method, a gravure coating method, and a die coating method.

In addition, examples of the method of curing the liquid crystal composition include a method including achieving a desired alignment state of the liquid crystal composition and fixing the alignment state by polymerization.

Here, the polymerization conditions are not particularly limited, and ultraviolet rays are preferably used in the polymerization by light irradiation. The irradiation dose is preferably 10 mJ/cm² to 50 J/cm², more preferably 20 mJ/cm² to 5 J/cm², even more preferably 30 mJ/cm² to 3 J/cm², and particularly preferably 50 to 1,000 mJ/cm². In order to promote the polymerization reaction, the treatment may be performed under heating conditions.

The thickness of the first optically anisotropic layer is not particularly limited, and is preferably 0.1 to 10 μm, and more preferably 0.5 to 5 μm.

In the optical laminate according to the embodiment of the present invention, the first optically anisotropic layer is preferably a positive A plate due to its usefulness as a circularly polarizing plate or a compensation layer for a liquid crystal display device.

Furthermore, in the optical laminate according to the embodiment of the present invention, the second optically anisotropic layer is preferably a positive C plate from the viewpoint of optical compensation of the first optically anisotropic layer in an oblique direction.

As another preferable aspect, in the optical laminate according to the embodiment of the present invention, the second optically anisotropic layer is preferably a positive A plate due to its usefulness as a compensation layer for a liquid crystal display device. Furthermore, in the optical laminate according to the embodiment of the present invention, the first optically anisotropic layer is preferably a positive C plate from the viewpoint of optical compensation of the second optically anisotropic layer in an oblique direction.

Here, the positive A plate and the positive C plate are defined as follows.

In a case where the refractive index in a slow axis direction in the film plane (in a direction in which the refractive index in the plane is maximum) is represented by nx, the refractive index in a direction orthogonal to the in-plane slow axis in the plane is represented by ny, and the refractive index in the thickness direction is represented by nz, the positive A plate satisfies a relationship represented by Expression (A1), and the positive C plate satisfies a relationship represented by Expression (C1). The Rth of the positive A plate shows a positive value, and the Rth of the positive C plate shows a negative value.

nx>ny≈nz Expression (A1)

nz>nx≈ny Expression (C1)

The symbol “≈” includes not only a case where both are exactly the same, but also a case where both are substantially the same.

Regarding the expression “substantially the same”, in the positive A plate, for example, “ny≈nz” also includes a case where (ny−nz)×d (where d is a film thickness) is −10 to 10 nm, and preferably −5 to 5 nm, and “nx≈nz” also includes a case where (nx−nz)×d is −10 to 10 nm, and preferably −5 to 5 nm. In addition, in the positive C plate, for example, “nx ≈ny” also includes a case where (nx−ny)×d (where d is a film thickness) is 0 to 10 nm, and preferably 0 to 5 nm.

In a case where the optically anisotropic layer is a positive A plate, Re (550) is preferably 100 to 180 nm, more preferably 120 to 160 nm, and even more preferably 130 to 150 nm from the viewpoint of functioning as a λ/4 plate or a view angle compensation plate for a liquid crystal cell.

Here, the “λ/4 plate” is a plate having a λ/4 function, and specifically, a plate having a function of converting linearly polarized light with a specific wavelength into circularly polarized light (or converting circularly polarized light into linearly polarized light).

In a case where the optically anisotropic layer is a positive C plate, the retardation in the thickness direction is not particularly limited, and the retardation in the thickness direction at a wavelength of 550 nm is preferably −10 to −160 nm, and more preferably −20 to −130 nm from the viewpoint that the reflectivity of the λ/4 plate in an oblique direction can be reduced, and that light leak of a view angle compensation plate for a liquid crystal cell in an oblique direction can be reduced.

[Polarizing Plate]

A polarizing plate according to the embodiment of the present invention has the above-described optical laminate according to the embodiment of the present invention and a polarizer.

In addition, the polarizing plate according to the embodiment of the present invention can be used as a circularly polarizing plate in a case where the above-described optical laminate according to the embodiment of the present invention is a λ/4 plate.

In a case where the polarizing plate according to the embodiment of the present invention is used as a circularly polarizing plate, the above-described optical laminate according to the embodiment of the present invention (particularly, first optically anisotropic layer) serves as a λ/4 plate (positive A plate), and the angle formed between a slow axis of the λ/4 plate and an absorption axis of the polarizer to be described later is preferably 30° to 60°, more preferably 40° to 50°, even more preferably 42° to 48°, and particularly preferably 45°.

In addition, the polarizing plate according to the embodiment of the present invention can also be used as an optical compensation film of a liquid crystal display device in IPS mode or FFS mode.

In a case where the polarizing plate according to the embodiment of the present invention is used as an optical compensation film of a liquid crystal display device in IPS mode or FFS mode, a laminate of a positive A plate and a positive C plate is used as the above-described optical laminate according to the embodiment of the present invention, and a slow axis of the positive A plate and an absorption axis of the polarizer to be described later are preferably orthogonal or parallel. Specifically, the angle formed between the slow axis of the positive A plate and the absorption axis of the polarizer to be described later is more preferably 0° to 5°, or 85° to 95°.

Here, the “slow axis” of the λ/4 plate or the positive A plate means a direction in which the refractive index in the plane of the λ/4 plate or the positive A plate is maximum, and the “absorption axis” of the polarizer means a direction in which the absorbance is the highest.

[Polarizer]

The polarizer of the polarizing plate according to the embodiment of the present invention is not particularly limited as long as it is a member having a function of converting light into specific linearly polarized light. An absorption type polarizer or a reflective type polarizer which has been known can be used.

As the absorption type polarizer, an iodine-based polarizer, a dye-based polarizer using a dichroic dye, a polyene-based polarizer, or the like is used. The iodine-based polarizer and the dye-based polarizer include a coating type polarizer and a stretching type polarizer, and any of these is applicable. A polarizer produced by adsorbing iodine or a dichroic dye to polyvinyl alcohol and performing stretching is preferable.

Examples of the method of obtaining a polarizer by performing stretching and dyeing in a state in which a laminate film is obtained by forming a polyvinyl alcohol layer on a base include JP5048120B, JP5143918B, JP4691205B, JP4751481B, and JP4751486B. These known technologies concerning a polarizer can also be preferably used.

As the reflective type polarizer, a polarizer obtained by laminating thin films having different birefringences, a wire grid type polarizer, a polarizer obtained by combining a cholesteric liquid crystal having a selective reflection area and a ¼ wavelength plate, or the like is used.

Among these, a polarizer including a polyvinyl alcohol-based resin (a polymer including —CH₂—CHOH— as a repeating unit, particularly, at least one selected from the group consisting of polyvinyl alcohol and an ethylene-vinyl alcohol copolymer) is preferable from the viewpoint of more excellent adhesiveness.

In the present invention, the thickness of the polarizer is not particularly limited, and is preferably 3 μm to 60 μm, more preferably 3 μm to 30 μm, and even more preferably 3 μm to 10 μm.

[Image Display Device]

An image display device according to the embodiment of the present invention is an image display device having the optical laminate according to the embodiment of the present invention or the circularly polarizing plate of the present invention.

The display element which is used in the image display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable, and a liquid crystal cell is more preferable. That is, the image display device according to the embodiment of the present invention is preferably a liquid crystal display device using a liquid crystal cell as a display element or an organic EL display device using an organic EL display panel as a display element.

The liquid crystal cell which is used in the liquid crystal display device is preferably a vertical alignment (VA) mode, an optically compensated bend (OCB) mode, an in-plane-switching (IPS) mode, a fringe-field-switching (FFS) mode, or a twisted nematic (TN) mode, but is not limited thereto.

The liquid crystal display device as an example of the image display device according to the embodiment of the present invention preferably has an aspect in which it has a polarizer, the optical laminate according to the embodiment of the present invention, and a liquid crystal cell in this order from the visible side, and more preferably has an aspect in which it has a polarizer, the above-described positive C plate, the above-described positive A plate, and a liquid crystal cell in this order from the visible side.

Suitable examples of the organic EL display device include a device having an aspect in which it has a polarizer, the optical laminate according to the embodiment of the present invention, and an organic EL display panel in this order from the visible side.

The organic EL display panel is a member in which a light emitting layer or a plurality of organic compound thin films including a light emitting layer is formed between a pair of electrodes of an anode and a cathode. In addition to the light emitting layer, a hole injection layer, a hole transport layer, an electron injection layer, an electron transport layer, a protective layer, and the like may be provided, and each of these layers may have a different function. Various materials can be used to form the respective layers.

### EXAMPLES

Hereinafter, the present invention will be more specifically described with examples. Materials, used amounts, ratios, treatment contents, treatment procedures, and the like shown in the following examples are able to be properly changed unless the changes cause deviance from the gist of the present invention. Therefore, the range of the present invention will not be restrictively interpreted by the following examples.

[Synthesis Examples]

[Synthesis of Monomer mB-1]

As shown in the following scheme, 2-hydroxyethyl methacrylate (13.014 g, 100 mmol), toluene (100 g), and dibutylhydroxytoluene (BHT) (10.0 mg) were put into a 200 ml three-neck flask comprising a stirrer, a thermometer, and a reflux condenser, and stirred at room temperature (23° C.). Next, to the obtained solution, 10-camphorsulfonic acid (230.3 mg, 0.1 mmol) was added, and the mixture was stirred at room temperature. Next, to the obtained solution, 2-(perfluorohexyl)ethyl vinyl ether (39.014 g, 100 mmol) was added dropwise for 1.5 hours, and the mixture was further stirred at room temperature for 3 hours. To the obtained solution, ethyl acetate (200 mL) and sodium bicarbonate water (200 mL) were added to perform separation and purification, and an organic phase was extracted. Magnesium sulfate was added to the obtained organic phase. The resulting organic phase was dried and filtered, and then from the obtained filtrate, the solvent was distilled off to obtain 46.8 g of a monomer mB-1 represented by Formula mB-1.

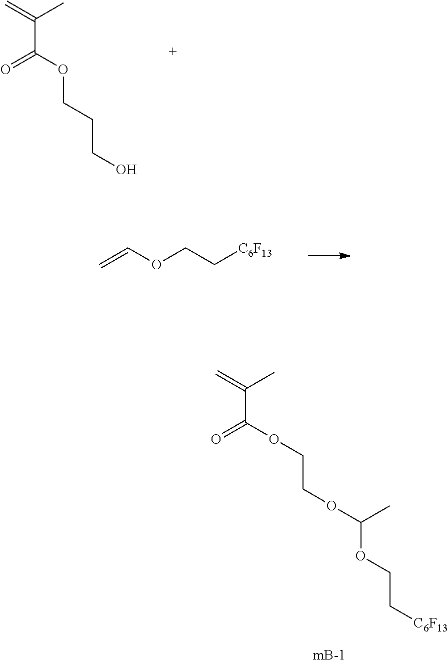

[Synthesis of Monomer mC-1]

According to the following scheme, a monomer mC-1 represented by Formula mC-1 was synthesized.

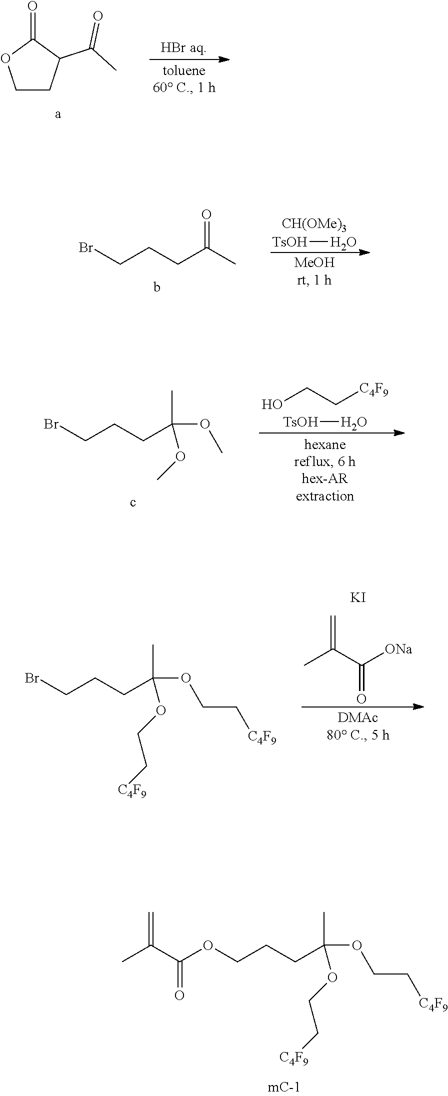

<Synthesis of b>

In a 2000 mL eggplant flask, 200 g of 2-acetylbutyrolactone (a compound represented by Formula a in the above scheme), 320 g of an aqueous hydrogen bromide solution (48%), and 300 mL of toluene were weighed and stirred for 1 hour at 60° C. The reaction solution was cooled to room temperature and transferred to a separating funnel, and 100 mL of hexane was added thereto. With 100 mL of saturated sodium hydrogen carbonate water containing 10 g of sodium thiosulfate added thereto and 100 mL of saturated saline, separation and washing were performed, and the obtained organic phase was dried with anhydrous magnesium sulfate and concentrated to obtain 260.0 g of a compound b (a compound represented by Formula b in the above scheme) as a brown liquid.

<Synthesis of c>

In a 2000 mL eggplant flask, 256 g of the compound b, 165.6 g of trimethyl formate, 9 g of p-toluenesulfonic acid monohydrate, and 400 mL of methanol were weighed and stirred for 1 hour at room temperature. 15 mL of diisopropylethylamine was added, and the solvent was distilled off by an evaporator. 500 mL of hexane and 50 mL of ethyl acetate were added and transferred to a separating funnel, and separation and washing were performed twice with 500 mL of an aqueous saturated sodium hydrogen carbonate solution. The obtained organic phase was dried with anhydrous magnesium sulfate and concentrated to obtain 248.0 g of a compound c (a compound represented by Formula c in the above scheme) as a brown liquid.

<Synthesis of d>

In a 500 mL eggplant flask, 50 g of the compound c, 0.45 g of p-toluenesulfonic acid monohydrate, 172.5 g of 1H,1H,2H,2H-perfluorohexane-1-ol, and 100 mL of hexane were weighed, and Dean-Stark was mounted at 77° C. The mixture was stirred for 6 hours, and a reaction solution was obtained.

Then, 1 mL of diisopropylethylamine was added to the reaction solution, and the solvent was distilled off by an evaporator to obtain a concentrated solution. The concentrated solution was transferred to a separating funnel, and 700 mL of hexane and 400 mL of acetonitrile were added thereto. Then, the hexane phase was fractionated and concentrated by an evaporator to obtain 73.0 g of a compound d (a compound represented by Formula d in the above scheme) as a brown liquid.

<Synthesis of Monomer mC-1>

In a 300 mL eggplant flask, 50 g of the compound d, 50 mg of BHT, 1.23 g of potassium iodide, 12 g of sodium methacrylate, and 50 mL of N,N-dimethylacetamide were weighed and stirred for 5 hours at 80° C. The mixture was cooled to room temperature, and 200 mL of water was added thereto. Then, the mixture was stirred for 5 minutes and transferred to a separating funnel, and 200 mL of hexane and 20 mL of ethyl acetate were added thereto. After shaking the separating funnel, the water layer was removed. An aqueous saturated sodium chloride solution was added to perform separation and washing. The obtained organic phase was dried with anhydrous sodium sulfate and concentrated, and column chromatography was performed to obtain 41 g of a monomer mC-1.

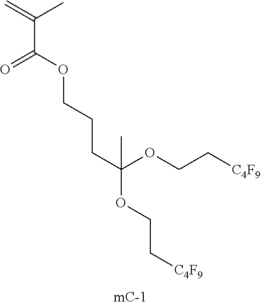

Monomers other than the above monomers were synthesized with reference to the above-described synthesis method and known methods (for example, the method described in WO2018/216812A).

### Example 1

[Synthesis of Photo-Alignment Polymer]

5.5 parts by mass of the following monomer mA-125 and 10 parts by mass of 2-butanone as a solvent were put into a flask comprising a cooling pipe, a thermometer, and a stirrer, and refluxing was performed by heating in a water bath with nitrogen flowing into the flask at 5 mL/min. Here, a solution obtained by mixing 3.0 parts by mass of the monomer mB-1, 1.5 parts by mass of the following monomer mD-1, 0.062 parts by mass of 2,2′-azobis(isobutyronitrile) as a polymerization initiator, and 13 parts by mass of 2-butanone as a solvent was added dropwise thereto for 3 hours, and the mixture was stirred while maintaining the refluxing state for 3 hours. After completion of the reaction, the reaction mixture was allowed to cool to room temperature, and 10 parts by mass of 2-butanone was added for dilution to obtain about 20 mass % of a polymer solution. The obtained polymer solution was poured into a large excess of methanol to precipitate the polymer, and the recovered precipitate was separated by filtering and washed with a large amount of methanol. Then, the resulting material was subjected to blast drying at 50° C. for 12 hours, and thus a photo-alignment polymer P-1 was obtained.

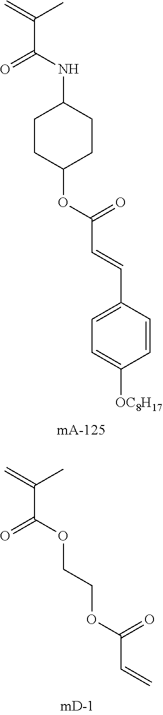

[Manufacturing of Optical Laminate]

<Production of Support>

A cellulose acylate film (TD40UL, manufactured by FUJIFILM Corporation) passed through dielectric heating rolls at a temperature of 60° C., and after the film surface temperature was raised to 40° C., an alkali solution having the following composition was applied to one surface of the film using a bar coater at a coating rate of 14 ml/m², and heated to 110° C.

Next, the obtained film was transported for 10 seconds under a steam-type far-infrared heater manufactured by NORITAKE CO., LIMITED.

Next, using a bar coater, pure water was applied in the same manner to the obtained film at 3 ml/m².

Next, water washing by a fountain coater and dewatering by an air knife were repeatedly performed on the obtained film three times. Then, the film was transported to a drying zone at 70° C. for 10 seconds and dried to produce an alkali-saponified cellulose acylate film, and the film was used as a support.

Composition of Alkali Solution

| | |
|---|---|
| Potassium Hydroxide | 4.7 parts by mass |
| Water | 15.8 parts by mass |
| Isopropanol | 63.7 parts by mass |
| Surfactant (C₁₄H₂₉O(CH₂CH₂₀)₂₀H) | 1.0 part by mass |
| Propylene Glycol | 14.8 parts by mass |

<Formation of Alignment Layer>

An alignment layer coating liquid having the following composition was continuously applied to an elongated cellulose acetate film saponified as described above by a #14 wire bar coater. After application, the obtained film was dried by hot air at 60° C. for 60 seconds, and further dried by hot air at 100° C. for 120 seconds. In the following composition, “Polymerization Initiator (IN1)” represents a photopolymerization initiator (IRGACURE 2959, manufactured by BASF SE).

Next, a rubbing treatment was continuously performed on the dried coating film to form an alignment layer. In this case, the longitudinal direction of the elongated film was parallel to the transport direction, and the rotation axis of a rubbing roller was in a clockwise direction of 45° with respect to the longitudinal direction of the film.

Composition of Alignment Layer Coating Liquid

| | |
|---|---|
| Following Modified Polyvinyl Alcohol | 10.0 parts by mass |
| Water | 371.0 parts by mass |
| Methanol | 119.0 parts by mass |
| Glutaric Aldehyde | 0.5 parts by mass |
| Polymerization Initiator (INI) | 0.3 parts by mass |

(In the following structural formulae, the ratio indicates a molar ratio)

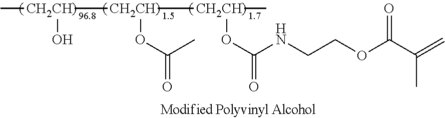

<Formation of Second Optically Anisotropic Layer>

The following rod-like liquid crystal compound A (80 parts by mass), the following rod-like liquid crystal compound B (20 parts by mass), a photopolymerization initiator (IRGACURE 819, manufactured by BASF SE) (3 parts by mass), the following photo-acid generator (B-1-1) (5.0 parts by mass), the following vertical alignment agent A (1 part by mass), the following vertical alignment agent B (0.5 parts by mass), and the above-described photo-alignment polymer P-1 (3.0 parts by mass) were dissolved in 215 parts by mass of methyl ethyl ketone to prepare a liquid crystal layer forming solution. The prepared liquid crystal layer forming solution was applied to the above-mentioned alignment layer by a #3.0 wire bar coater, heated for 2 minutes at 70° C., and cooled to 40° C. Then, irradiation with 500 mJ/cm² of ultraviolet rays was performed thereon using a 365 nm UV-LED while nitrogen purge was conducted to make an atmosphere with an oxygen concentration of 1.0 vol % or less. Then, by performing annealing for 1 minute at 120° C., a second optically anisotropic layer was formed.

The second optically anisotropic layer was a positive C plate satisfying Expression (C1) nz>nx≈ny, and had a film thickness of about 1 μm.

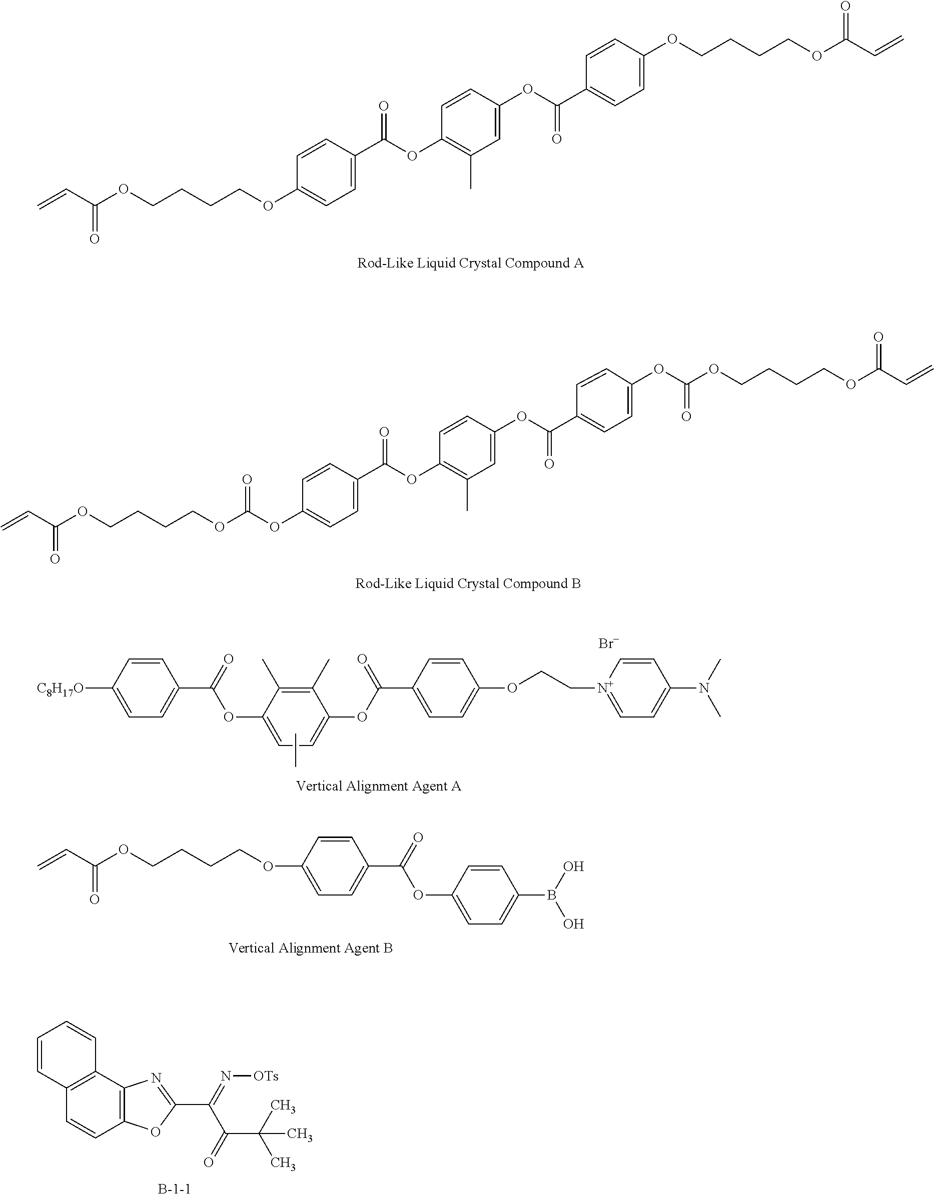

<Irradiation Step (Impartation of Alignment Function)>

The obtained second optically anisotropic layer was irradiated with 7.9 mJ/cm² of UV light (ultra-high pressure mercury lamp; UL750; manufactured by HOYA CANDEO OPTRONICS CORPORATION) (wavelength: 313 nm) passing through a wire grid type polarizer at room temperature to impart an alignment function.

Of the repeating units of the photo-alignment polymer P-1, the repeating unit formed of the monomer mB-1 was converted into a repeating unit B-1 represented by Formula B-1 by the action of light in the irradiation step.

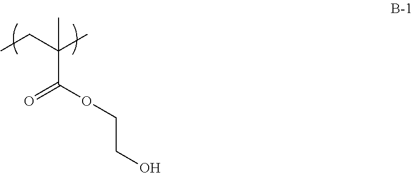

<Formation of First Optically Anisotropic Layer (Upper Layer)>

The above-described rod-like liquid crystal compound A (80 parts by mass), the above-described rod-like liquid crystal compound B (20 parts by mass), a photopolymerization initiator (IRGACURE 907, manufactured by BASF SE) (3 parts by mass), a sensitizer (KAYACURE DETX, manufactured by Nippon Kayaku Co., Ltd.) (1 part by mass), and the following horizontal alignment agent (0.3 parts by mass) were dissolved in methyl ethyl ketone (193 parts by mass) to prepare an optically anisotropic layer forming solution.

The above-described optically anisotropic layer forming solution was applied to the second optically anisotropic layer having the alignment function imparted thereto by a wire bar coater #7, and heated for 2 minutes at 60° C., and at the temperature maintained at 60° C., irradiation with 300 mJ/cm² of ultraviolet rays was performed thereon using a 160 W/cm air-cooled metal halide lamp (manufactured by Eye Graphics Co., Ltd.) while nitrogen purge was conducted to make an atmosphere with an oxygen concentration of 1.0 vol % or less. Thus, a first optically anisotropic layer was formed, and an optical laminate was produced. The first optically anisotropic layer was a positive A plate satisfying Expression (A1) nx>ny ≈nz, and had a film thickness of 2.5 μm.

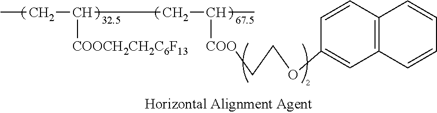

### Examples 2 to 6 and Comparative Examples 1 and 2

Photo-alignment polymers P-2 to P-6, H-1, and H-2 were synthesized in the same manner as in the case of the photo-alignment polymer P-1 synthesized in Example 1, except that monomers capable of forming the following repeating units, respectively, were used as monomers forming the repeating units shown in the following Table 1.

In addition, optical laminates were produced to have the same film thicknesses as those in Example 1 in the same manner as in Example 1, except that in the manufacturing of the optical laminate, the photo-alignment polymers P-2 to P-6, H-1, and H-2 were used instead of the photo-alignment polymer P-1.

The symbols in the following Table 1 have the following meanings, respectively. In addition, as a monomer capable of forming a repeating unit represented by Formula B-1, the above-described monomer mB-1 was used as in Example 1.

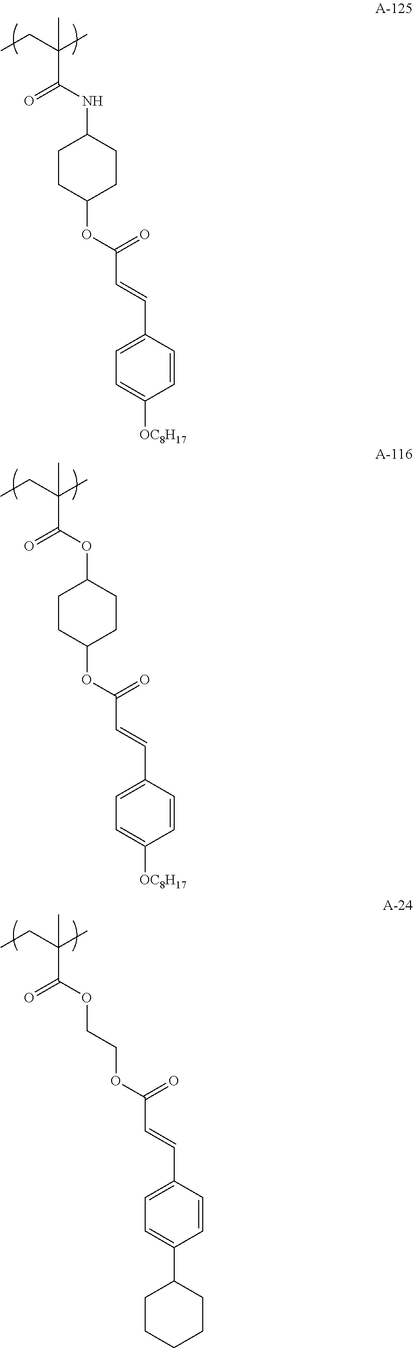

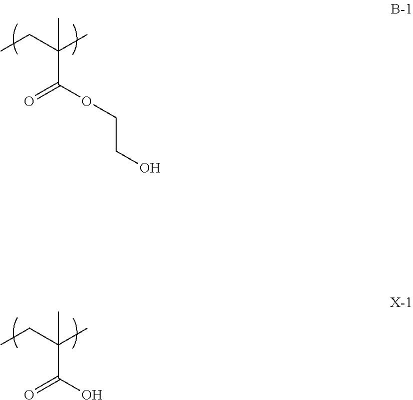

### Example 7

<Formation of Second Optically Anisotropic Layer>

The above-described rod-like liquid crystal compound A (83 parts by mass), the following rod-like liquid crystal compound C (15 parts by mass), the following rod-like liquid crystal compound D (2 parts by mass), an acrylate monomer (A-400, manufactured by SHIN-NAKAMURA CHEMICAL CO., LTD.) (4 parts by mass), the following hydrophilic polymer (2 parts by mass), the above-described vertical alignment agent A (2 parts by mass), the following photopolymerization initiator B-2 (4 parts by mass), the following photo-acid generator (B-3) (3 parts by mass), and the above-described photo-alignment polymer P-1 (3.0 parts by mass) were dissolved in 680 parts by mass of methyl isobutyl ketone to prepare a liquid crystal layer forming solution.

The prepared liquid crystal layer forming solution was applied to a cellulose-based polymer film (TG40, manufactured by FUJIFILM Corporation) by a #3.0 wire bar coater, heated for 2 minutes at 70° C., and irradiated with 200 mJ/cm² of ultraviolet rays using a 365 nm UV-LED while nitrogen purge was conducted to make an atmosphere with an oxygen concentration of 100 ppm or less. Then, by performing annealing for 1 minute at 120° C., a second optically anisotropic layer was formed.

The second optically anisotropic layer was a positive C plate satisfying Expression (C1) nz>nx≈ny, and had a film thickness of about 0.5 μm.

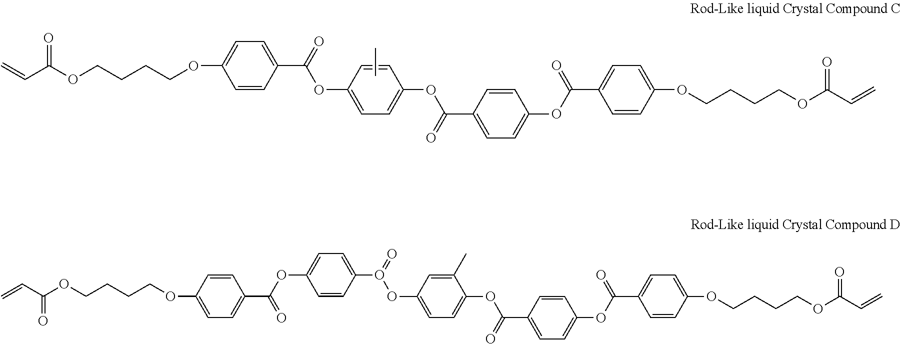

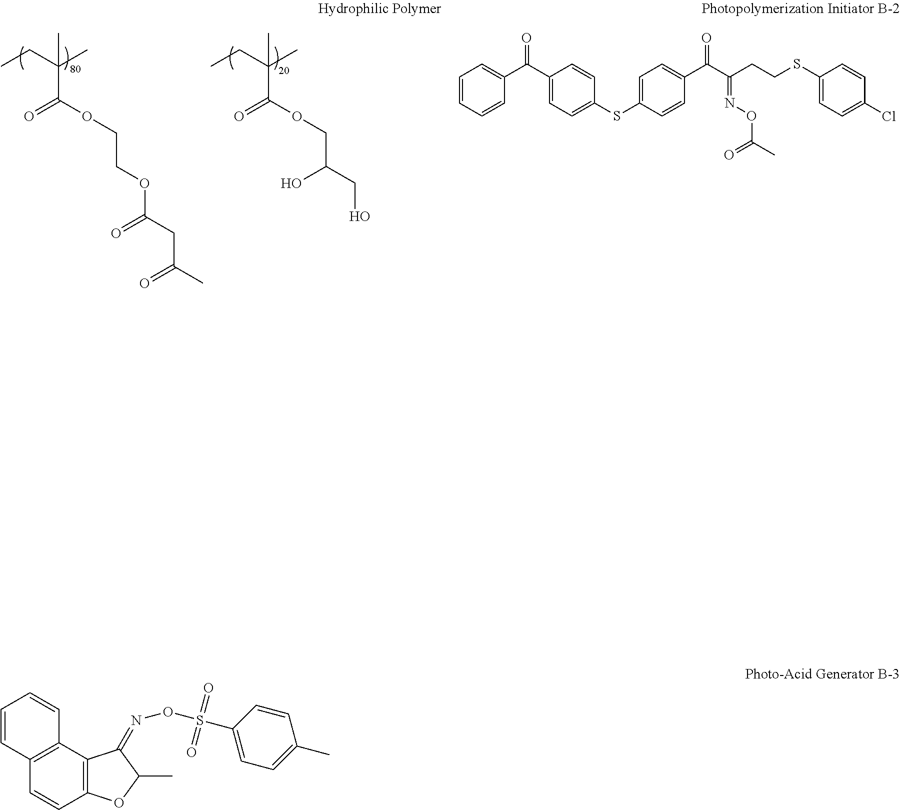

<Irradiation Step (Impartation of Alignment Function)>

The obtained second optically anisotropic layer was irradiated with 7.9 mJ/cm² of UV light (ultra-high pressure mercury lamp; UL750; manufactured by HOYA CANDEO OPTRONICS CORPORATION) (wavelength: 313 nm) passing through a wire grid type polarizer at room temperature to impart an alignment function.

<Formation of First Optically Anisotropic Layer (Upper Layer)>

An optically anisotropic layer forming solution was prepared in the same manner as in Example 1, except that instead of the rod-like liquid crystal compound A (80 parts by mass) and the rod-like liquid crystal compound B (20 parts by mass), the following polymerizable liquid crystal compound E (65 parts by mass) and the following polymerizable liquid crystal compound F (35 parts by mass) were used, and as a solvent, cyclopentanone (246 parts by mass), methyl ethyl ketone (73 parts by mass), and bis(2-(2-methoxyethoxy)ethyl)ether (14 parts by mass) were used.

A first optically anisotropic layer was formed in the same manner as in Example 1, except that the above-described optically anisotropic layer forming solution was used on the second optically anisotropic layer having the alignment function imparted thereto, and an optical laminate was produced. The first optically anisotropic layer was a positive A plate satisfying Expression (A1) nx>ny≈nz, and had a film thickness of 3.0 μm.

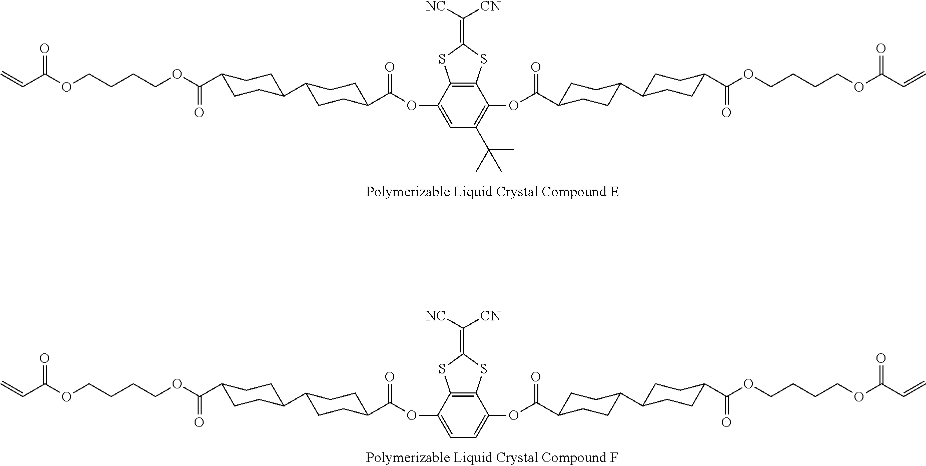

### Example 8

<Synthesis of Photo-Alignment Polymer P-8>

A photo-alignment polymer P-8 was synthesized in the same manner as in the case of the photo-alignment polymer P-1 synthesized in Example 1, except that the monomer mC-1 capable of forming the following repeating unit C-1 was used as a monomer forming the repeating unit shown in the following Table 1.

The following repeating unit C-1 is a unit formed by converting the repeating unit formed of the monomer mC-1 by the action of light in the irradiation step.

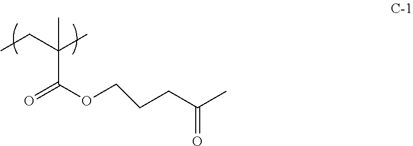

<Formation of Second Optically Anisotropic Layer>

A second optically anisotropic layer was formed to have the same film thickness as that in Example 7 in the same manner as in Example 7, except that the photo-alignment polymer P-8 (0.8 parts by mass) was used instead of the photo-alignment polymer P-1 (3.0 parts by mass) and 0.2 part by mass of diisopropylethylamine was further added.

<Formation of First Optically Anisotropic Layer>

The above-described polymerizable liquid crystal compound E (45 parts by mass), the above-described polymerizable liquid crystal compound F (22 parts by mass), the following rod-like liquid crystal compound G (5 parts by mass), the above-described rod-like liquid crystal compound A (6.5 parts by mass), the above-described rod-like liquid crystal compound C (1.2 parts by mass), the above-described rod-like liquid crystal compound D (0.2 parts by mass), the following polymerizable liquid crystal compound H (20 parts by mass), a photopolymerization initiator B-2 (0.5 parts by mass), and the following surfactant (0.1 parts by mass) were dissolved in cyclopentanone (246 parts by mass), methyl ethyl ketone (73 parts by mass), and bis(2-(2-methoxyethoxy)ethyl)ether (14 parts by mass) to prepare an optically anisotropic layer forming solution.

The optically anisotropic layer forming solution was applied to the second optically anisotropic layer having the alignment function imparted thereto by a wire bar coater #7, heated for 2 minutes at 120° C., cooled to 60° C., and irradiated with 80 mJ/cm² of ultraviolet rays using a 365 nm UV-LED while nitrogen purge was conducted to make an atmosphere with an oxygen concentration of 100 ppm or less. Then, a first optically anisotropic layer was formed by heating to 120° C. and irradiation with 250 mJ/cm² of ultraviolet rays using a high-pressure mercury lamp, and an optical laminate was produced. The first optically anisotropic layer was a positive A plate satisfying Expression (A1) nx>ny≈nz, and had a film thickness of 2.8 μm.

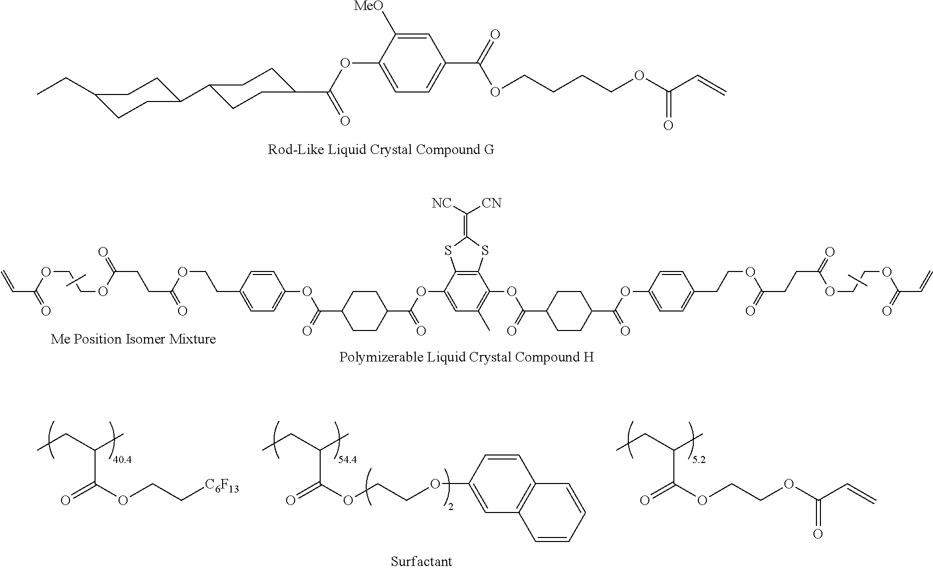

### Example 9

<Formation of Second Optically Anisotropic Layer>

An optically anisotropic layer forming composition 2 having the following composition was prepared.

Optically Anisotropic Layer Forming Composition 2

| | |
|---|---|
| Following Polymerizable Liquid Crystal | 42.00 parts by mass |
| Compound R1 | |
| Following Polymerizable Liquid Crystal | 42.00 parts by mass |
| Compound R2 | |
| Following Polymerizable Compound A1 | 12.00 parts by mass |
| Following Polymerizable Compound A2 | 4.00 parts by mass |
| Above Photopolymerization Initiator B-2 | 0.50 parts by mass |
| San-Aid SI-B3A | 3.00 parts by mass |
| DIPEA (KOEI CHEMICAL CO., LTD.) | 0.15 parts by mass |
| Following Photo-Alignment Polymer P-9 | 0.23 parts by mass |
| HISOLVE MTEM (manufactured by | 2.00 parts by mass |

TOHO Chemical Industry Co., Ltd.)

| | |
|---|---|
| NK Ester A-200 (manufactured by SHIN- | 1.00 part by mass |

NAKAMURA CHEMICAL CO., LTD.)

| | |
|---|---|
| Methyl Isobutyl Ketone | 300.00 parts by mass |

The group adjacent to the acryloyloxy group of the following liquid crystal compounds R1 and R2 represents a propylene group (group in which a methyl group was substituted with an ethylene group). Each of the following liquid crystal compounds R1 and R2 represents a mixture of regioisomers with different methyl group positions.

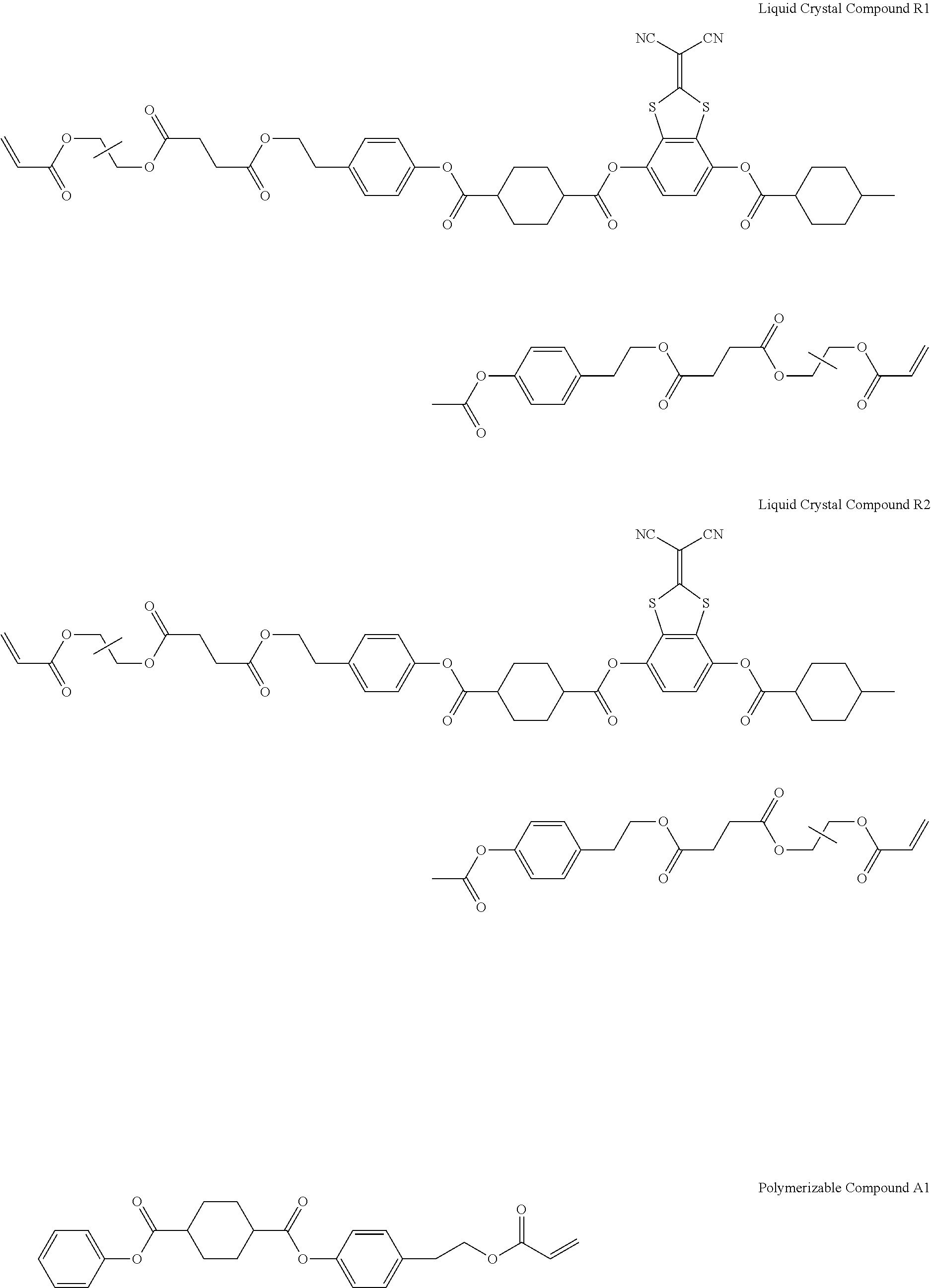

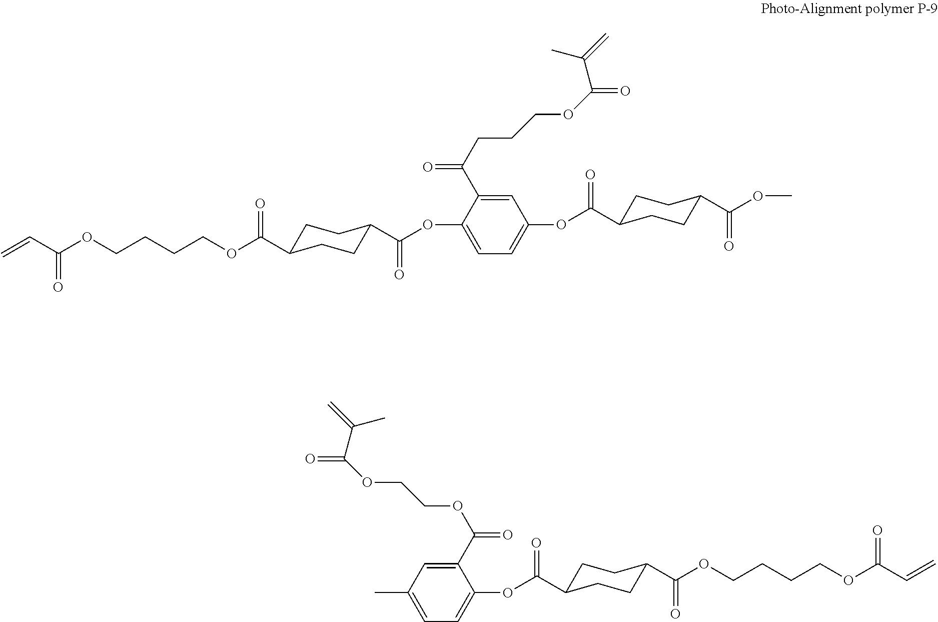 [SMILES: C=CC(=O)OCCCCOC(=O)C1CCC(C(=O)Oc2ccc(OC(=O)C3CCC(C(=O)OC)CC3)cc2C(=O)CCCOC(=O)C(=C)C)CC1 ; C=CC(=O)OCCCCOC(=O)C1CCC(C(=O)Oc2ccc(C)cc2C(=O)OCCOC(=O)C(=C)C)CC1]

(In the following formulae: a to c satisfy a:b:c=26:20:54, and each represents the content (mol %) of each repeating unit with respect to all the repeating units in the polymer.)

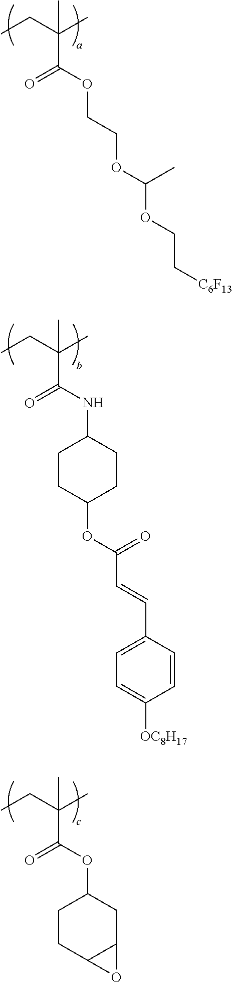

The above-described optically anisotropic layer forming composition 2 was applied to a cellulose acylate film (TG40UL, manufactured by FUJIFILM Corporation) by a wire bar coater #7, and annealed for 1 minute at 120° C. to crosslink the photo-alignment polymer P-9. Due to the annealing, the cleavage group contained in the repeating unit represented by the content a in the above formula is cleaved, and crosslinking by the repeating unit represented by the content c occurs.

Then, the temperature was reduced to room temperature, and a photo-alignment treatment including irradiation with 7.9 mJ/cm² of UV light (ultra-high pressure mercury lamp; UL750; manufactured by HOYA CANDEO OPTRONICS CORPORATION) (wavelength: 313 nm) passing through a wire grid type polarizer was performed.

Then, after heating 1 minute at 120° C. for alignment and aging of the liquid crystal compound, the temperature was reduced to 60° C. While the temperature was maintained at 60° C., irradiation with 200 mJ/cm² of ultraviolet rays was performed using a 365 nm UV-LED while nitrogen purge was conducted to make an atmosphere with an oxygen concentration of 100 ppm or less, and a second optically anisotropic layer (thickness: 2.5 μm) was produced. The second optically anisotropic layer was a positive A plate satisfying Expression (A1) nx>ny≈nz.

<Formation of First Optically Anisotropic Layer>

An optically anisotropic layer forming composition 1 prepared with the following composition was applied to the second optically anisotropic layer by a wire bar coater #4.

Then, the composition was heated for 90 seconds with hot air at 70° C. in order to dry the solvent of the composition and to align and age the liquid crystal compound. Ultraviolet irradiation (300 mJ/cm²) was performed at 40° C. with an oxygen concentration of 0.1% under a nitrogen purge to fix the alignment of the liquid crystal compound, and a first optically anisotropic layer was thus produced on the second optically anisotropic layer. The obtained first optically anisotropic layer was a positive C plate satisfying Expression (C1) nz>nx≈ny, and had a thickness of about 1.5 μm.

Optically Anisotropic Layer Forming Composition 1

| | | |
|---|---|---|
| Above Liquid Crystal Compound R1 | 10.0 | parts by mass |
| Above Liquid Crystal Compound R2 | 54.0 | parts by mass |
| Mixture of Above Rod-Like Liquid Crystal | 28.0 | parts by mass |
| Compounds A, C, and D with 83:15:2 | | |
| (mass ratio) | | |
| Above Polymerizable Compound A2 | 8.0 | parts by mass |
| Following Compound B1 | 4.5 | parts by mass |
| A-600 (SHIN-NAKAMURA CHEMICAL | 12.0 | parts by mass |
| CO., LTD.) | | |
| Above Photopolymerization Initiator B-2 | 3.0 | parts by mass |
| Following Leveling Agent P2 | 0.16 | parts by mass |
| Following Leveling Agent P3 | 0.20 | parts by mass |
| Methyl Ethyl Ketone | 225.0 | parts by mass |
| Methanol | 12.5 | parts by mass |
| Isopropanol | 12.5 | parts by mass |

Compound B1

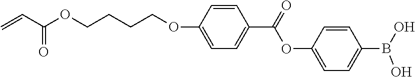 [SMILES: C=CC(=O)OCCCCOc1ccc(C(=O)Oc2ccc(B(O)O)cc2)cc1]

Leveling Agent P2 (weight-average molecular weight: 15,000, the numerical value in the following formula represents mass %)

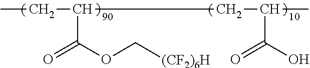

Leveling Agent P3 (weight-average molecular weight: 11,200)

(In the following formulae: a to d satisfy a:b:c:d =56:10:29:5, and each represents the content (mol %) of each repeating unit with respect to all the repeating units in the polymer.)

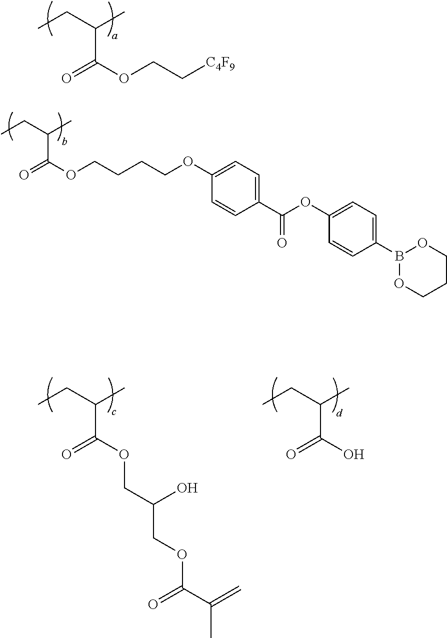

### Example 10

Optically anisotropic layers were formed in the same manner as in Example 9, except that the liquid crystal compounds R1 and R2 in the optically anisotropic layer forming compositions 1 and 2 were changed to the following liquid crystal compound Z1, and the polymerizable compounds A1 and A2 were changed to the following polymerizable compound A3.

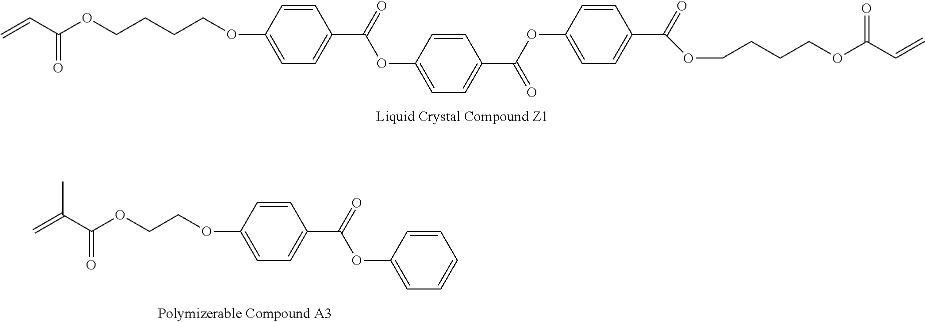

[Evaluation]

In each of the produced optical laminates, a surface (surface layer A) of the second optically anisotropic layer on the side in contact with the first optically anisotropic layer was confirmed by the above-described method, and it was possible to confirm that a photo-alignment polymer having a photo-alignment group and a hydroxyl group is present in Examples 1 to 7, 9, and 10. In addition, it was possible to confirm that a photo-alignment polymer having a photo-alignment group and a ketone group is present in Example 8. In contrast, it was not possible to confirm the presence of a photo-alignment polymer having a photo-alignment group and a polar group in Comparative Examples 1 and 2. It was possible to confirm that a photo-alignment polymer having a photo-alignment group and a carboxy group is present in the surface layer A in Comparative Examples 1 and 2.

[Liquid Crystal Alignment Properties]

Two polarizing plates were installed in crossed Nicols. The produced optical laminate was installed therebetween to observe the degree of light leak, and evaluation was performed based on the following criteria. The results are shown in the following Table 1.

A: There is no light leak.

B: Light leak rarely occurs.

C: Light leak is observed in some parts, but is within the permissible range.

D: Light leak is observed in the whole surface.

[Cissing]

Optical laminates for evaluation were produced in the same manner as in the examples and the comparative examples, except that the number of the wire bar coater for applying the optically anisotropic layer forming solution was changed to #2.2 in the formation of the first optically anisotropic layer.

Next, two polarizing plates were installed in crossed Nicols, and the produced optical laminate for evaluation was installed diagonally therebetween in A4 size. Defects looking like missing circles or ellipses were regarded as cissing, and evaluation was performed based on the following criteria. The results are shown in the following Table 1.

A: No defects were shown.

B: One or two defects were shown.

C: Three to five defects were shown.

D: Six or more defects were shown.

TABLE 1

| | | | | | | | | | | | Comparative | |
|---|---|---|---|---|---|---|---|---|---|---|---|---|
| | Examples | | | | | | | | | | Examples | |
| | 1 | 2 | 3 | 4 | 5 | 6 | 7 | 8 | 9 | 10 | 1 | 2 |
| Repeating Unit A | A-125 | A-125 | A-125 | A-116 | A-125 | A-125 | A-125 | A-125 | A-125 | A-125 | A-125 | A-24 |
| (photo-alignment group) | | | | | | | | | | | | |
| Repeating Unit B | B-1 | B-1 | B-1 | B-1 | B-1 | B-1 | B-1 | C-1 | B-1 | B-1 | — | — |
| (polar group) | | | | | | | | | | | | |
| Other Repeating Units | — | — | — | — | — | — | — | — | — | — | X-1 | x-1 |
| (carboxy group) | | | | | | | | | | | | |
| Molar Ratio | 1.3 | 0.8 | 4.0 | 1.3 | 0.5 | 6.0 | 13 | 1.0 | 1.3 | 1.3 | — | — |
| (polar group/photo-alignment group) | | | | | | | | | | | | |
| Liquid Crystal Alignment Properties | A | A | B | A | A | c | A | A | A | A | D | D |
| Cissing | A | B | A | A | C | A | A | A | A | A | A | A |

From the above results, it was found that in a case where a photo-alignment polymer having a photo-alignment group and a polar group is not present in the surface of the second optically anisotropic layer on the side in contact with the first optically anisotropic layer, the optically anisotropic layer provided as an upper layer has poor liquid crystal alignment properties (Comparative Examples 1 and 2).

In contrast, it was found that in a case where a photo-alignment polymer having a photo-alignment group and a polar group is present in the surface of the second optically anisotropic layer on the side in contact with the first optically anisotropic layer, the optically anisotropic layer provided as an upper layer has good liquid crystal alignment properties (Examples 1 to 10).

In addition, from the comparison between Examples 1 and 7, it was found that the optically anisotropic layer provided as an upper layer has good liquid crystal alignment properties even in an aspect in which an alignment layer for forming the second optically anisotropic layer is not provided. In addition, in the measurement by XPS, fluorine or silicon was not detected in the surface of the second optically anisotropic layer on the side in contact with the first optically anisotropic layer in Examples 1 to 8 and Comparative Examples 1 and 2.

What is claimed is:

1. An optical laminate comprising:
a first optically anisotropic layer; and
a second optically anisotropic layer,
wherein the first and second optically anisotropic layers are directly laminated,
each of the first and second optically anisotropic layers consists of a liquid crystal layer, and
a photo-alignment polymer having a photo-alignment group and at least one type of polar group selected from the group consisting of a hydroxyl group and a ketone group is present in a surface of the second optically anisotropic layer on a side in contact with the first optically anisotropic layer.

2. The optical laminate according to claim 1,
wherein a molar ratio of the polar group to the photo-alignment group is 0.8 to 4.0.

3. The optical laminate according to claim 1,
wherein the photo-alignment group is a cinnamoyl group bonded to a main chain of the photo-alignment polymer via a linking group containing a cycloalkane ring.

4. The optical laminate according to claim 1,
wherein the polar group is bonded to a main chain of the photo-alignment polymer via a linking group containing an aliphatic hydrocarbon group having one or more carbon atoms.

5. The optical laminate according to claim 1,
wherein fluorine or silicon is substantially not present in the surface of the second optically anisotropic layer on the side in contact with the first optically anisotropic layer.

6. The optical laminate according to claim 1,
wherein the first optically anisotropic layer is a positive A plate.

7. The optical laminate according to claim 1,
wherein the second optically anisotropic layer is a positive C plate.

8. The optical laminate according to claim 1,
wherein the first optically anisotropic layer is a positive C plate.

9. The optical laminate according to claim 1,
wherein the second optically anisotropic layer is a positive A plate.

10. A polarizing plate comprising:
the optical laminate according to claim 1; and
a polarizer.

11. An image display device comprising:
the optical laminate according to claim 1.

12. An image display device comprising:
the polarizing plate according to claim 10.
